(19) United States
(12) Patent Application Publication
(10) Pub. No.: US 2026/0339204 A1
(43) Pub. Date: Oct. 29, 2026

(54) PHOTOSENSITIVE RESIN COMPOSITION, RESIN FILM, AND ELECTRONIC DEVICE

(71) Applicant: SUMITOMO BAKELITE CO., LTD., Tokyo (JP)

(72) Inventors: Yuma TANAKA, Tokyo (JP); Ritsuya KAWASAKI, Tokyo (JP)

(73) Assignee: SUMITOMO BAKELITE CO., LTD., Tokyo (JP)

(21) Appl. No.: 19/109,898

(22) PCT Filed: Aug. 31, 2023
(86) PCT No.: PCT/JP2023/031925

§ 371 Date: Mar. 7, 2025

(30) Foreign Application Priority Data
Sep. 8, 2022 (JP) 2022-142797

(51) Int. Cl. G03F 7/038; G03F 7/004

(52) U.S. Cl. CPC G03F 7/0387; G03F 7/0045

(57) ABSTRACT

The photosensitive resin composition of the present invention includes a polyimide (A) having an imide ring structure in the molecule, and a photosensitizer (B), in which a moisture content measured by the Karl Fischer method is 0.30% by mass or more and 10% by mass or less.

### TECHNICAL FIELD

The present invention relates to a photosensitive resin composition, a resin film, and an electronic device.

### BACKGROUND ART

In the electrical and electronic fields, photosensitive resin compositions including polyamide resin and/or polyimide resin may be used to form cured films for insulating layers or the like.

For this reason, photosensitive resin compositions including polyamide resin and/or polyimide resin have been studied.

Patent Document 1 describes a photosensitive resin composition including a polyimide resin and a photopolymerization initiator.

### RELATED DOCUMENT

### Patent Document

[Patent Document 1] Japanese Unexamined Patent Application, First Publication No. 2018-070829A

### SUMMARY OF THE INVENTION

### Technical Problem

However, as a result of the present inventors' studies, it was discovered that the photosensitive resin composition described in Patent Document 1 has room for improvement in terms of storage stability and copper adhesion stability.

### Solution to Problem

When the present inventors carried out further studies, it was found that appropriately controlling the range of the moisture content in a photosensitive resin composition including polyimide makes it possible to improve the storage stability of the photosensitive resin composition and also to improve the copper adhesion stability between a resin film formed of the photosensitive resin composition and a metal base material including copper, thereby completing the present invention.

According to one aspect of the present invention, the following photosensitive resin composition, resin film, and electronic device are provided.
1. A photosensitive resin composition including a polyimide (A) having an imide ring structure in a molecule, and a photosensitizer (B), in which a moisture content measured by a Karl Fischer method is 0.30% by mass or more and 10% by mass or less.
2. The photosensitive resin composition according to 1, in which the moisture content is 0.5% by mass or more and 6% by mass or less.
3. The photosensitive resin composition according to 1 or 2, in which, when a number of moles of imide ring groups included in the polyimide (A) is defined as IM and a number of moles of amide groups included in the polyimide (A) is defined as AM, an imide cyclization rate expressed as {IM/(IM+AM)}×100(%) is 90% or more.
4. The photosensitive resin composition according to any one of 1 to 3, in which a weight-average molecular weight of the polyimide (A) is 27,000 or more.
5. The photosensitive resin composition according to any one of 1 to 4, further including a silane coupling agent (C).
6. The photosensitive resin composition according to 5, in which the silane coupling agent (C) includes a silane coupling agent including an acid anhydride group, and/or a silane coupling agent having a structure in which a part of a structure derived from an acid anhydride group is ring-opened.
7. The photosensitive resin composition according to any one of 1 to 6, further including an epoxy compound.
8. The photosensitive resin composition according to 7, in which the epoxy compound includes a compound having one or more epoxy-containing groups and one or more (meth)acryloyl groups in one molecule.
9. The photosensitive resin composition according to any one of 1 to 8, further including an organic solvent, in which the photosensitive resin composition is varnish-like.
10. The photosensitive resin composition according to any one of 1 to 9, in which a total solid content concentration in the photosensitive resin composition is 10% to 50% by mass.
11. The photosensitive resin composition according to any one of 1 to 10, in which a glass transition temperature of a cured film of the photosensitive resin composition is 200 °C or higher.
12. The photosensitive resin composition according to any one of 1 to 11, in which a 90° peel strength fluctuation number according to a method below is 70% or less,

### Method

the photosensitive resin composition is coated by spin coating onto a 12-inch silicon wafer having a 3000 Å plated copper layer over a surface such that a film thickness after drying is 10 μm, and then heated at 120 °C for 3 minutes to obtain a photosensitive resin film, next, the photosensitive resin film is exposed to light at 300 mJ/cm² through a photomask using an i-line stepper such that a range 6.5 mm wide and 50 mm long is exposed to light, next, the photosensitive resin film is developed with cyclopentanone and propylene glycol monomethyl ether acetate together with the silicon wafer using a spray developer, further air-dried using a spin dryer, then dried over a hot plate at 120 °C for 2 minutes, and then heat-treated in a nitrogen atmosphere at 200 °C for 90 minutes to obtain a cured film, next, the silicon wafer is cut such that the cured film 6.5 mm wide and 50 mm long remains, and a longitudinal direction end (5 mm) of the cured film is immersed in a 2% aqueous hydrofluoric acid solution at 23 °C for 6 hours, and then washed with water and dried to obtain an evaluation substrate with an end of the film peeled off, next, 1 cm of the evaluation substrate is peeled off using a 90° peel strength measuring device under a condition of a peel speed of 20 mm/min, and a maximum value of the peel strength at this time is measured as a peel strength, and then, ten samples are measured, an average value of the peel strengths of the ten samples is calculated as the peel strength, and a measurement variation in the ten samples calculated from a formula below is set as the 90° peel strength fluctuation number,

fluctuation number[%]=(maximum value−minimum value)/average value×100.
13. The photosensitive resin composition according to any one of 1 to 12, in which, when a viscosity of the photosensitive resin composition is defined as no and a viscosity of the photosensitive resin composition after leaving the photosensitive resin composition to stand for 7 days at 23 °C is defined as η₁, a value of η₁/η₀ is 1.5 or less.
14. The photosensitive resin composition according to any one of 1 to 13, in which the photosensitizer (B) includes a photoradical generator.
15. The photosensitive resin composition according to any one of 1 to 14, in which the photosensitive resin composition is a negative-type photosensitive resin composition.
16. A resin film formed of a cured product of the photosensitive resin composition according to any one of 1 to 15.
17. An electronic device including the resin film according to 16.
18. A method for producing a photosensitive resin composition, the method including a step of obtaining a photosensitive resin composition by dissolving a polyimide (A) having an imide ring structure in a molecule and a photosensitizer (B) in a solvent, in which the step of obtaining the photosensitive resin composition has a step of adjusting a moisture content in the photosensitive resin composition measured by a Karl Fischer method to be 0.30% by mass or more and 10% by mass or less.
19. The method for producing a photosensitive resin composition according to 18, the method further including a step of preparing an aqueous solution including a silane coupling agent (C) and water, and adding the aqueous solution to the photosensitive resin composition.

### Advantageous Effects of Invention

According to the present invention, a photosensitive resin composition having excellent storage stability and copper adhesion stability and a resin film and an electronic device using the same are provided.

### BRIEF DESCRIPTION OF THE DRAWINGS

FIG. 1 is a longitudinal cross-sectional view showing an example of a configuration of an electronic device.

FIG. 2 is a partial enlarged view of a region surrounded by a dashed line in FIG. 1.

FIG. 3 is a step diagram showing a method for producing the electronic device shown in FIG. 1.

FIG. 4 is a diagram for illustrating the method for producing the electronic device shown in FIG. 1.

FIG. 5 is a diagram for illustrating the method for producing the electronic device shown in FIG. 1.

FIG. 6 is a diagram for illustrating the method for producing the electronic device shown in FIG. 1.

### DESCRIPTION OF EMBODIMENTS

A description will be given below of an embodiment of the present invention using the drawings. In all the drawings, similar components are given similar reference numerals and explanations thereof will not be repeated as appropriate. In addition, the drawings are schematic diagrams and do not correspond to the actual dimensional ratios.

An explanation will be given of an overview of the photosensitive resin composition of the present embodiment.

The photosensitive resin composition of the present embodiment includes a polyimide (A) having an imide ring structure in the molecule, and a photosensitizer (B), in which the moisture content in the photosensitive resin composition measured by the Karl Fischer method is 0.30% by mass or more and 10% by mass or less.

According to the findings of the present inventors, it was discovered that setting the moisture content in the photosensitive resin composition to the lower limit value or more makes it possible to suppress production variations in the adhesion strength (90° peel strength) between a resin film formed of the photosensitive resin composition and a copper base material and thus to improve the copper adhesion stability. Although the detailed mechanism is unclear, it is presumed that the state where a predetermined amount or more of moisture is included in the composition makes it possible to suppress the performance of the composition from falling outside of a predetermined range when storage environment conditions, such as humidity, change. For example, when the photosensitive resin composition includes a silane coupling agent, it is considered that the silanolization state will be stabilized even when the humidity environment changes.

In addition, it was discovered that the use of the polyimide (A) having an imide ring structure in a photosensitive resin composition including a predetermined amount or more of moisture makes it possible to suppress viscosity changes in the photosensitive resin composition after storage and thus to improve the storage stability. In addition, it is also possible to suppress reduction in the elongation of the resin films formed of the photosensitive resin composition.

Meanwhile, it was discovered that setting the moisture content in the photosensitive resin composition to the above upper limit value or less makes it possible to suppress deterioration in the appearance of the photosensitive resin composition over time from immediately after preparation and thus to improve the storage stability.

The lower limit of the moisture content in the photosensitive resin composition measured by the Karl Fischer method is 0.30% by mass or more, preferably 0.5% by mass or more, and more preferably 0.6% by mass or more. Due to this, it is possible to reduce the 90° peel strength fluctuation number and to improve the copper adhesion stability.

In addition, from the viewpoint of further improving the storage stability and the copper adhesion stability, the lower limit of the moisture content in the photosensitive resin composition measured by the Karl Fischer method is even more preferably 1.0% by mass or more, even more preferably 1.5% by mass or more, even more preferably 1.8% by mass or more, even more preferably 2.0% by mass or more, even more preferably 2.3% by mass or more, and even more preferably 2.5% by mass or more.

Meanwhile, the upper limit of the moisture content in the photosensitive resin composition is 10% by mass or less, preferably 6% by mass or less, and more preferably 5% by mass or less. Due to this, it is possible to suppress the generation of turbidity and precipitation in the varnish-like photosensitive resin composition.

In addition, from the viewpoint of suppressing the generation of turbidity or precipitation in the varnish-like photosensitive resin composition while further improving the storage stability and copper adhesion stability, the moisture content in the photosensitive resin composition measured by the Karl Fischer method is preferably 0.5% by mass or more and 10% by mass or less, more preferably 1.0% by mass or more and 10% by mass or less, even more preferably 1.5% by mass or more and 10% by mass or less, even more preferably 2.0% by mass or more and 10% by mass or less, even more preferably 2.5% by mass or more and 10% by mass or less, even more preferably 2.5% by mass or more and 6% by mass or less, and even more preferably 2.5% by mass or more and 5% by mass.

All of the values of the moisture content in the photosensitive resin composition are values of the water content ratio when the total amount of the photosensitive resin composition (varnish) including the solvent is 100% by mass.

From another viewpoint, when the amount of the total solid content (non-volatile components) excluding the solvent in the photosensitive resin composition of the present embodiment is 100 parts by mass, the moisture content measured by the Karl Fischer method is, from the viewpoint of further improving the storage stability and copper adhesion stability, preferably more than 5.0 parts by mass, more preferably 5.5 parts by mass or more, even more preferably 6.0 parts by mass or more, even more preferably 7.0 parts by mass or more, even more preferably 8.0 parts by mass or more, even more preferably 8.5 parts by mass or more, and even more preferably 9.0 parts by mass or more, and is preferably 36.0 parts by mass or less, more preferably 32.0 parts by mass or less, even more preferably 28.0 parts by mass or less, even more preferably 24.0 parts by mass or less, even more preferably 20.0 parts by mass or less, and even more preferably 18.0 parts by mass or less.

In the present embodiment, examples of the method for measuring the moisture content in the photosensitive resin composition include the following method.

Using a Karl Fischer moisture meter and moisture vaporizer and using a Karl Fischer reagent as a titration reagent, the mass (mg) of water generated from the photosensitive resin composition when heated to 170 °C under the condition of a nitrogen gas flow rate of 250 mL/min is measured in accordance with the volumetric titration method specified in JIS K 0113:2005. Next, the water content ratio when the total amount of the photosensitive resin composition (varnish or solid content) is 100% by mass is determined and set as the moisture content (% by mass).

It is possible to use the photosensitive resin composition of the present embodiment as a negative-type photosensitive resin composition. A resin film (cured film) formed of the photosensitive resin composition is obtained by a heating treatment after exposure to light.

The photosensitive resin composition of the present embodiment is preferably used to form permanent films, protective films, insulating films, and rewiring materials in electronic devices.

Here, the term “electronic device” refers to elements, devices, final products, and other general electrical equipment that utilizes electronic engineering technology, such as semiconductor chips, semiconductor elements, printed wiring boards, electric circuits, display devices such as television receivers and monitors, information communication terminals, light-emitting diodes, physical batteries, and chemical batteries.

In addition, it is also possible to apply the photosensitive resin composition of the present embodiment to the production of optical waveguides. Specifically, it is possible to apply the photosensitive resin composition of the present embodiment to the formation of a core layer and/or a clad layer of an optical waveguide.

From another viewpoint, the photosensitive resin composition of the present embodiment is preferably applied to a pattern formation method that uses an organic solvent developer. A detailed description will be given below of the use of an organic solvent developer as a developer.

A detailed description will be given below of the composition of the photosensitive resin composition of the present embodiment.

### <Photosensitive Resin Composition>

The photosensitive resin composition of the present embodiment includes a polyimide (A) having an imide ring structure in the molecule.

(Polyimide (A) having Imide Ring Structure in Molecule)

A polyimide having an imide ring structure (may simply referred to below as “polyimide”) has an azole structure. It is possible for the photosensitive resin composition of the present embodiment to include one or two or more polyimides.

When the number of moles of imide ring groups included in the polyimide is IM and the number of moles of amide groups included in the polyimide is AM, an imide cyclization rate expressed as {IM/(IM+AM)}×100(%) is preferably 90% or more, more preferably 95% or more, and even more preferably 98% or more. In short, the polyimide resin is preferably a resin which has no or few amide structures and many imide ring structures. By using such a polyimide resin, dehydration due to the ring-closing reaction does not occur and it is thus possible to further inhibit shrinkage due to heating (curing shrinkage). Due to this, it is possible to achieve further improvements in the reliability of electronic devices and further improvements in the flatness of the cured film, and the like.

It is possible to find the imide cyclization rate, for example, from the area of the peaks corresponding to the amide groups or the area of the peaks corresponding to the imide ring groups in the NMR spectrum, or the like. As another example, it is possible to find the imide cyclization rate from the area of the peaks corresponding to the amide groups or the area of the peaks corresponding to the imide ring groups in the infrared absorption spectrum, or the like.

Specifically, for example, it is possible to determine the imide cyclization rate by measuring the ¹H-NMR spectrum of the polyimide (A) of the present embodiment and using the calculation formula {A_{IM}/(A_{IM}+A_{AM})}×100(%) where A_{AM} is the area of the peaks corresponding to the amide groups in the measured ¹H-NMR spectrum and A_{IM} is the area of the peaks corresponding to the imide ring groups.

Here, in the present specification, the imide cyclization rate is also referred to as the “imidization rate”.

The azole structure may be in the side chain of the polyimide or may be at the terminal. In view of the availability, ease of synthesis, and the like of the raw materials, the polyimide preferably has an azole structure at least at one terminal. The polyimide may have an azole structure at both terminals, or at only one terminal.

Preferable examples of the azole structure include a triazole structure and a tetrazole structure. There are two types of triazole structures: a 1,2,3-triazole structure and a 1,2,4-triazole structure, which differ in the position of the nitrogen atom. In the present embodiment, it is possible to use either type of triazole structure.

Examples of the triazole structure include monovalent groups obtained by removing hydrogen atoms from the triazole compounds listed below. However, from the viewpoint of particularly good copper adhesion in the present embodiment, the triazole structure is preferably a triazole structure that does not include a benzene ring skeleton.

Triazole, benzotriazole, tolyltriazole (benzotriazole with a methyl group substituted on the benzene ring, carboxybenzotriazole, 4,5,6,7-tetrahydrobenzotriazole, 4,5,6,7-tetrahydrotriazole, 2-(2′-hydroxy-5′-methylphenyl)benzotriazole, 2-(2′-hydroxy-5′-tert-butylphenyl)benzotriazole, 2-(2′-hydroxy-3′5′-di-tert-butylphenyl)benzotriazole, 2-(2′-hydroxy-4-octoxyphenyl)benzotriazole, and the like.

Examples of tetrazole structures include monovalent groups obtained by removing hydrogen atoms from the tetrazole compounds listed below. 1,2,3,4-tetrazole, 5-amino-1,2,3,4-tetrazole, 5-methyl-1,2,3,4-tetrazole, 1H-tetrazole-5-acetic acid, 1H-tetrazole-5-succinic acid.

More specifically, it is possible for the azole structure to include a structure represented by General Formula (AZ).

Here, the “*” indicates a bond to the polyimide.

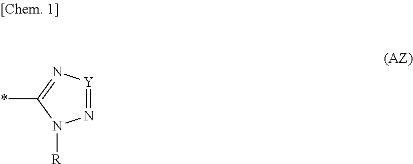

### (AZ)

In General Formula (AZ),
R is a hydrogen atom, a halogen atom, a substituted or unsubstituted alkyl group having 1 to 20 carbon atoms, a substituted or unsubstituted cycloalkyl group having 3 to 15 carbon atoms, or a substituted or unsubstituted aromatic hydrocarbon group having 6 to 20 carbon atoms, and
Y is —CH═ or —N═.

The alkyl group of R may be linear or branched. Examples of linear alkyl groups include methyl groups, ethyl groups, propyl groups, butyl groups, pentyl groups, hexyl groups, heptyl groups, octyl groups, nonyl groups, decanyl groups, undecyl groups, dodecyl groups, tridecyl groups, isotridecyl groups, tetradecyl groups, pentadecyl groups, hexadecyl groups, isohexadecyl groups, heptadecyl groups, octadecyl groups, nonadecyl groups, icosyl groups, henicosyl groups, docosyl groups, and the like. Examples of branched alkyl groups include 1-methylethyl groups, 1-methylpropyl groups, 2-methylpropyl groups, 1-methylbutyl groups, 2-methylbutyl groups, 3-methylbutyl groups, 1-ethylbutyl groups, 2-ethylbutyl groups, 1-methylpentyl groups, 2-methylpentyl groups, 3-methylpentyl groups, 4-methylpentyl groups, and the like.

The cycloalkyl group of R may be monocyclic or polycyclic. Specifically, examples thereof include cyclopropyl groups, cyclobutyl groups, cyclopentyl groups, cyclohexyl groups, cycloheptyl groups, cyclooctyl groups, and the like. In addition, examples of polycyclic alicyclic groups include norbornyl groups, isobornyl groups, tricyclononyl groups, tricyclodecyl groups, tetracyclododecyl groups, and the like.

Examples of the aromatic hydrocarbon groups of R include phenyl groups, naphthyl groups, anthranyl groups, and the like.

The polyimide of the present embodiment may have other functional groups in the side chain. When the polyimide of the present embodiment has other functional groups in the side chain, the other functional groups are preferably functional groups having 1 to 20 carbon atoms which may include unsaturated bonds, and more preferably functional groups having 1 to 10 carbon atoms which may include unsaturated bonds.

The polyimide preferably includes a polyimide including fluorine atoms. A finding of the present inventors was that polyimides including fluorine atoms tend to have better organic solvent solubility than polyimides not including fluorine atoms. For this reason, using a polyimide including fluorine atoms makes it easier to give the photosensitive resin composition varnish-like properties.

The amount (mass ratio) of the fluorine atoms in the polyimide including fluorine atoms is, for example, 1 to 30% by mass, preferably 3 to 28% by mass, and more preferably 5 to 25% by mass. By including a large enough amount of fluorine atoms in the polyimide, sufficient organic solvent solubility is easily obtained. Meanwhile, from the viewpoint of balance with other performances, the amount of fluorine atoms is preferably not excessively large.

Meanwhile, from the viewpoint of improving environmental friendliness, the polyimide of the present embodiment preferably does not include fluorine atoms.

From the viewpoint of improving environmental friendliness, when the total amount of the polyimide is 100% by mass, the content of the fluorine atoms in the polyimide of the present embodiment is preferably 0% by mass or more and preferably 30% by mass or less, more preferably 20% by mass or less, even more preferably 10% by mass or less, even more preferably 5% by mass or less, even more preferably 3% by mass or less, even more preferably 1% by mass or less, even more preferably 0.5% by mass or less, and even more preferably 0.1% by mass or less.

The polyimide preferably includes a structural unit represented by General Formula (a).

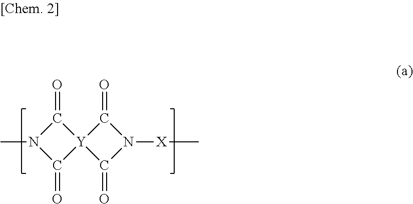

In General Formula (a),
X is a divalent organic group,
Y is a tetravalent organic group, and
at least one of X and Y is a fluorine atom-containing group.

The divalent organic group of X and/or the tetravalent organic group of Y preferably includes an aromatic ring structure and more preferably includes a benzene ring structure. The above tends to further increase the heat resistance.

From the viewpoint of the organic solvent solubility, both X and Y are preferably fluorine atom-containing groups.

The divalent organic group of X and/or the tetravalent organic group of Y preferably have a structure in which 2 to 6 benzene rings are bonded through single bonds or divalent linking groups. Examples of the divalent linking groups here include alkylene groups, fluorinated alkylene groups, ether groups, and the like. The alkylene groups and fluorinated alkylene groups may be linear or branched.

The divalent organic group of X has, for example, 6 to 30 carbon atoms.

The tetravalent organic group of Y has, for example, 6 to 20 carbon atoms. The two imide rings in General Formula (a) are each preferably a five-membered ring.

The polyimide more preferably includes a structural unit represented by General Formula (aa).

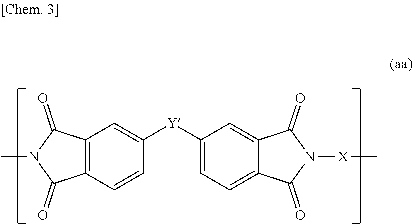

In General Formula (aa),
Y′ represents a single bond or an alkylene group, and
X has the same meaning as X in General Formula (a).

The alkylene group of Y′ may be linear or branched. Some or all of the hydrogen atoms of the alkylene group of Y′ are preferably substituted with fluorine atoms. The number of carbon atoms of the alkylene group of Y′ is, for example, 1 to 6, preferably 1 to 4, and more preferably 1 to 3.

Meanwhile, from the viewpoint of improving environmental friendliness, the polyimide of the present embodiment preferably includes a structural unit represented by General Formula (a) in which X and Y are organic groups not containing fluorine atoms and more preferably includes a structural unit represented by General Formula (aa) in which X and Y′ are organic groups not containing fluorine atoms.

The polyimide may be soluble or insoluble in an alkaline developer. Whether the polyimide is designed to be soluble in an alkaline developer depends on whether the photosensitive resin composition of the present embodiment is applied to development using an alkaline developer or to development using an organic solvent-based developer.

As described below, the photosensitive resin composition of the present embodiment is preferably applied to development using an organic solvent-based developer. In this respect, the polyimide is preferably substantially insoluble in an alkaline developer.

In other words, the polyimide preferably does not have an alkali-soluble group such as a phenolic hydroxy group or a carboxy group, or has such a group only in a small amount.

Specifically, the ratio of structural units having an alkali-soluble group in the polyimide is preferably 0 to 10 mol % and more preferably 0 to 5 mol % of the total structural units. In addition, specifically, the ratio of structural units having a phenolic hydroxyl group in the polyimide is preferably 0 to 10 mol % and more preferably 0 to 5 mol % of the total structural units.

In other words, when the polyimide has a structural unit represented by General Formula (a) or a structural unit represented by General Formula (aa), these structural units preferably do not have an alkali-soluble group such as a phenolic hydroxyl group or a carboxyl group.

Typically, it is possible to obtain polyimides by (i) first synthesizing a polyamide by reacting (condensation polymerization) a diamine with an acid dianhydride, (ii) then imidizing the polyamide (ring-closing reaction), and (iii) introducing a desired functional group into the polymer terminal as necessary.

Alternatively, in the above step (i), a compound including an azole structure may be reacted with the diamine and the acid dianhydride, and the above step (iii) may not be carried out. Examples of the compound including an azole structure to be reacted in the above step (i) include an azole compound having an amino group, specifically, an azole compound in which the “*” portion in General Formula (AZ) is an amino group or an amino group-containing group. In the Examples below, the polyimide is synthesized by this method. For the specific reaction conditions, refer to the Examples below.

In the finally obtained polyimide, the diamine is incorporated into the polymer as the divalent organic group X in General Formula (a). In addition, the acid dianhydride is incorporated into the polymer as the tetravalent organic group Y in General Formula (a).

In the synthesis of polyimide, it is possible to use one or two or more diamines and it is possible to use one or two or more acid dianhydrides.

Examples of the diamine raw material include 3,4′-diaminodiphenyl ether (3,4′-ODA), 4,4′-diamino-2,2′-bis(trifluoromethyl)biphenyl (TFMB), 3,3′,5,5′-tetramethylbenzidine, 2,3,5,6-tetramethyl-1,4-phenylenediamine, 3,3′-diaminodiphenyl sulfone, 3,3′dimethylbenzidine, 3,3′-bis(trifluoromethyl)benzidine, 2,2′-bis (p-aminophenyl)hexafluoropropane, bis(trifluoromethoxy)benzidine (TFMOB), 2,2′-bis(pentafluoroethoxy)benzidine (TFEOB), 2,2′-trifluoromethyl-4,4′-oxydianiline (OBABTF), 2-phenyl-2-trifluoromethyl-bis(p-aminophenyl)methane, 2-phenyl-2-trifluoromethyl-bis(m-aminophenyl)methane, 2,2′-bis(2-heptafluoroisopropoxy-tetrafluoroethoxy)benzidine (DFPOB), 2,2-bis(m-aminophenyl)hexafluoropropane (6-FmDA), 2,2-bis(3-amino-4-methylphenyl)hexafluoropropane, 3,6-bis(trifluoromethyl)-1,4-diaminobenzene (2TFMPDA), 1-(3,5-diaminophenyl)-2,2-bis(trifluoromethyl)-3,3,4,4,5,5,5-heptafluoropentane, 3,5-diaminobenzotrifluoride (3,5-DABTF), 3,5-diamino-5-(pentafluoroethyl)benzene, 3,5-diamino-5-(heptafluoropropyl)benzene, 2,2′-dimethylbenzidine (DMBZ), 2,2′,6,6′-tetramethylbenzidine (TMBZ), 3,6-diamino-9,9-bis(trifluoromethyl)xanthene (6FCDAM), 3,6-diamino-9-trifluoromethyl-9-phenylxanthene (3FCDAM), 3,6-diamino-9,9-diphenylxanthene, 2,2′-bis(trifluoromethyl)benzidine, 4,4′-diamino-3,3′-diethyl-5,5′-dimethyldiphenylmethane, and the like. Naturally, the usable diamines are not limited only to the above examples. It is possible to use one type or two or more types of diamines.

Among the above, from the viewpoint of further improving storage stability and copper adhesion stability, the diamines used in the synthesis of the polyimide of the present embodiment preferably include one type or two or more types selected from the group consisting of 2,2′-bis(trifluoromethyl)benzidine and 4,4′-diamino-3,3′-diethyl-5,5′-dimethyldiphenylmethane.

Examples of the raw material acid dianhydrides include pyromellitic anhydride (PMDA), diphenylether-3,3′,4,4′-tetracarboxylic dianhydride (ODPA), benzophenone-3,3′,4,4′-tetracarboxylic dianhydride (BTDA), biphenyl-3,3′,4,4′-tetracarboxylic dianhydride (BPDA), diphenylsulfone-3,3′,4,4′-tetracarboxylic dianhydride (DSDA), diphenylmethane-3,3′,4,4′-tetracarboxylic dianhydride, 2,2-bis(3,4-phthalic anhydride)propane, 2,2-bis(3,4-phthalic anhydride)-1,1,1,3,3,3-hexafluoropropane (6FDA), 4,4′-(hexafluoroisopropylidene)diphthalic anhydride, 4,4′-oxydiphthalic dianhydride, 4-[4-(1,3-dioxoisobenzofuran-5-ylcarbonyloxy)-2,3,5-trimethylphenyl]-2,3,6-trimethylphenyl, 1,3-dioxoisobenzofuran-5-carboxylate, and the like. Naturally, the usable acid dianhydrides are not limited only to the above examples. It is possible to use one type or two or more types of acid dianhydrides.

Among the above, from the viewpoint of further improving storage stability and copper adhesion stability, the acid dianhydride used in the synthesis of the polyimide of the present embodiment preferably includes one type or two or more types selected from the group consisting of 4,4′-(hexafluoroisopropylidene)diphthalic anhydride, 4,4′-oxydiphthalic dianhydride, 4-[4-(1,3-dioxoisobenzofuran-5-ylcarbonyloxy)-2,3,5-trimethylphenyl]-2,3,6-trimethylphenyl, and 1,3-dioxoisobenzofuran-5-carboxylate.

The usage ratio of diamine to acid dianhydride is basically 1:1 in molar ratio. However, in order to obtain a desired terminal structure, one of the two may be used in excess. Specifically, by using an excess of diamine, the terminals (both terminals) of the polyimide easily become amino groups. Meanwhile, by using an excess of acid dianhydride, the terminals (both terminals) of the polyimide easily become acid anhydride groups. When a polyimide having an acid anhydride group at the terminal is obtained in the reaction system and an azole compound having an amino group reacts with the acid anhydride group, a polyimide having an azole structure at the terminal is obtained.

The amino group and/or acid anhydride group at the terminal of the polyimide obtained by condensation polymerization may be reacted with a reagent to give the polyimide terminal a desired functional group.

The weight-average molecular weight of the polyimide is, for example, 5,000 to 100,000, preferably 7,000 to 75,000, and more preferably 10,000 to 50,000. By setting the weight-average molecular weight of the polyimide to be large to a certain degree, it is possible to obtain, for example, sufficient heat resistance in the cured film. In addition, by having a weight-average molecular weight of the polyimide that is not excessively large, the polyimide is easily dissolved in an organic solvent.

Usually, it is possible to determine the weight-average molecular weight by the gel permeation chromatography (GPC) method using polystyrene as a standard substance.

Specifically, examples thereof include a method using a polystyrene equivalent value determined from a standard polystyrene calibration curve obtained by gel permeation chromatography (GPC) measurement using THF as a solvent under conditions of a measurement temperature of 40 °C and a sample concentration of 0.5 wt %.

Meanwhile, from the viewpoint of further improving storage stability and copper adhesion stability, the weight-average molecular weight of the polyimide of the present embodiment is preferably 27,000 or more, more preferably 30,000 or more, even more preferably 33,000 or more, even more preferably 35,000 or more, even more preferably 37,000 or more, even more preferably 40,000 or more, even more preferably 50,000 or more, even more preferably 60,000 or more, and even more preferably 70,000 or more, and is preferably 200,000 or less, more preferably 150,000 or less, even more preferably 120,000 or less, even more preferably 100,000 or less, and even more preferably 90,000 or less.

From the viewpoint of further improving storage stability and copper adhesion stability, when the total amount of the photosensitive resin composition (varnish) is 100% by mass, the content of the polyimide in the present embodiment is preferably 5% by mass or more, more preferably 8% by mass or more, even more preferably 10% by mass or more, even more preferably 12% by mass or more, even more preferably 14% by mass or more, and even more preferably 15% by mass or more, and is preferably 50% by mass or less, more preferably 40% by mass or less, even more preferably 30% by mass or less, even more preferably 25% by mass or less, even more preferably 22% by mass or less, and even more preferably 20% by mass or less.

### (Photosensitizer (B))

The photosensitive resin composition of the present embodiment includes a photosensitizer.

The photosensitizer is not particularly limited as long as it is possible to generate active species using light to cure the photosensitive resin composition.

The photosensitizer preferably includes a photoradical generator. Photoradical generators are particularly effective for polymerizing polyfunctional (meth)acrylate compounds.

The usable photoradical generators are not particularly limited and it is possible to use any known photoradical generator as appropriate.

Examples thereof include alkylphenone-based compounds such as 2,2-diethoxyacetophenone, 2,2-dimethoxy-2-phenylacetophenone, 1-hydroxycyclohexyl phenyl ketone, 2-hydroxy-2-methyl-1-phenylpropan-1-one, 1-[4-(2-hydroxyethoxy)phenyl]-2-hydroxy-2-methyl-1-propan-1-one, 2-hydroxy-1-{4-[4-(2-hydroxy-2-methylpropionyl)benzyl]phenyl}-2-methylpropan-1-one, 2-methyl-1-(4-methylthiophenyl)-2-morpholinopropan-1-one, 2-benzyl-2-dimethylamino-1-(4-morpholinophenyl)-butanone-1, and 2-(dimethylamino)-2-[(4-methylphenyl)methyl]-1-[4-(4-morpholinyl)phenyl]-1-butanone; benzophenone-based compounds such as benzophenone, 4,4′-bis(dimethylamino)benzophenone, and 2-carboxybenzophenone; benzoin-based compounds such as benzoin methyl ether, benzoin ethyl ether, benzoin isopropyl ether, and benzoin isobutyl ether; thioxanthone-based compounds such as thioxanthone, 2-ethylthioxanthone, 2-isopropylthioxanthone, 2-chlorothioxanthone, 2,4-dimethylthioxanthone, and 2,4-diethylthioxanthone; halomethylated triazine-based compounds such as 2-(4-methoxyphenyl)-4,6-bis (trichloromethyl)-s-triazine, 2-(4-methoxynaphthyl)-4,6-bis (trichloromethyl)-s-triazine, 2-(4-ethoxynaphthyl)-4,6-bis(trichloromethyl)-s-triazine, and 2-(4-ethoxycarboxylnaphthyl)-4,6-bis(trichloromethyl)-s-triazine; halomethylated oxadiazole-based compounds such as 2-trichloromethyl-5-(2′-benzofuryl)-1,3,4-oxadiazole, 2-trichloromethyl-5-[-(2′-benzofuryl)vinyl]-1,3,4-oxadiazole, 4-oxadiazole, and 2-trichloromethyl-5-furyl-1,3,4-oxadiazole; biimidazole-based compounds such as 2,2′-bis(2-chlorophenyl)-4,4′,5,5′-tetraphenyl-1,2′-biimidazole, 2,2′-bis(2,4-dichlorophenyl)-4,4′,5,5′-tetraphenyl-1,2′-biimidazole, and 2,2′-bis(2,4,6-trichlorophenyl)-4,4′,5,5′-tetraphenyl-1,2′-biimidazole; oxime ester-based compounds such as 1,2-octanedione, 1-[4-(phenylthio)phenyl]-2-(O-benzoyloxime), ethanone, and 1-[9-ethyl-6-(2-methylbenzoyl)-9H-carbazol-3-yl]-,1-(O-acetyloxime); titanocene-based compounds such as bis(η5-2,4-cyclopentadiene-1-yl)-bis(2,6-difluoro-3-(1H-pyrrol-1-yl)-phenyl)titanium; benzoic acid ester-based compounds such as p-dimethylaminobenzoic acid and p-diethylaminobenzoic acid; acridine-based compounds such as 9-phenylacridine, and the like. Among the above, it is possible to particularly preferably use oxime ester-based compounds.

When a photosensitizer is used, only one photosensitizer may be used, or two or more photosensitizers may be used.

The content of the photosensitizer is, for example, 1 to 30 parts by mass and preferably 5 to 20 parts by mass with respect to 100 parts by mass of the polyfunctional (meth)acrylate compound.

### (Silane Coupling Agent (C))

The photosensitive resin composition of the present embodiment may include a silane coupling agent (C). When a silane coupling agent is used, only one silane coupling agent may be used, or two or more silane coupling agents may be used. By using a silane coupling agent, it is possible to further increase the adhesion between the resin film formed by the photosensitive resin composition and the base material.

As the silane coupling agent, for example, it is possible to use silane coupling agents such as amino group-containing silane coupling agents, epoxy group-containing silane coupling agents, (meth)acryloyl group-containing silane coupling agents, mercapto group-containing silane coupling agents, vinyl group-containing silane coupling agents, ureido group-containing silane coupling agents, sulfide group-containing silane coupling agents, silane coupling agents having an acid anhydride group, and silane coupling agents having a structure in which a part of the structure derived from the acid anhydride group is ring-opened. Among the above, it is preferable to include a silane coupling agent including an acid anhydride group, and/or a silane coupling agent having a structure in which a part of the structure derived from the acid anhydride group is ring-opened.

In the present embodiment, in terms of compatibility with polyimide, a silane coupling agent having a cyclic anhydride structure, and/or a silane coupling agent having a structure in which a part of the structure derived from the acid anhydride group is ring-opened is preferably used. Although the details are unclear, it is presumed that the cyclic anhydride structure and/or carboxylic acid structure react easily with the main chain, side chain, and/or terminal of the polyimide, thereby obtaining a particularly good adhesion-improving effect.

When the usage amount of the polyimide (A) is 100 parts by mass, the usage amount of the silane coupling agent (C) in the photosensitive resin composition is, for example, 0.1 to 20 parts by mass, preferably 0.5 to 10 parts by mass, and more preferably 1 to 8 parts by mass.

### (Polyfunctional (Meth)Acrylate Compound)

The photosensitive resin composition of the present embodiment preferably includes a polyfunctional (meth)acryl compound.

The polyfunctional (meth)acryl compound refers to a compound having two or more (meth)acryloyl groups in one molecule. The polyfunctional (meth)acryl compound is considered to form a network structure that “wraps” the polyimide skeleton by polymerization. It is presumed that the formation of such a complexly intertwined structure improves the performance of the resin film.

There is no particular upper limit to the number of (meth)acryloyl groups in a polyfunctional (meth)acrylate compound, but the upper limit is, for example, approximately 11, due to the ease of obtaining raw materials and the like.

As a broad trend, when the number of (meth)acryloyl groups is large, the chemical resistance of the cured film tends to increase. Meanwhile, when the number of (meth)acryloyl groups is small, the mechanical and physical properties of the cured film, such as tensile elongation, tend to be good.

As an example of a polyfunctional (meth)acryl compound, it is possible to use a polyfunctional (meth)acryl compound represented by the following general formula. In the following general formula, R′ is a hydrogen atom or a methyl group, n is 0 to 3, and R is a hydrogen atom or a (meth)acryloyl group.

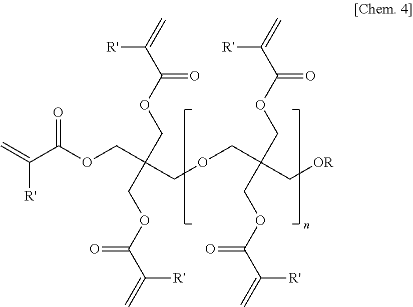

Specific examples of polyfunctional (meth)acryl compounds include the following. Naturally, the polyfunctional (meth)acryl compounds are not limited thereto.

Polyol polyacrylates such as ethylene glycol di(meth)acrylate, trimethylolpropane tri(meth)acrylate, ditrimethylolpropane tetra(meth)acrylate, pentaerythritol tri(meth)acrylate, pentaerythritol tetra(meth)acrylate, dipentaerythritol penta(meth)acrylate, and dipentaerythritol hexa(meth)acrylate, epoxy acrylates such as bisphenol A diglycidyl ether di(meth)acrylate and hexanediol diglycidyl ether di(meth)acrylate, urethane (meth)acrylates obtained by the reaction of polyisocyanate with hydroxyl group-containing (meth)acrylates such as hydroxyethyl (meth)acrylate, and the like.

Among the above, the polyfunctional (meth)acryl compound of the present embodiment preferably includes polyol polyacrylates from the viewpoint of further improving storage stability and copper adhesion stability and more preferably includes one or two or more selected from the group consisting of dipentaerythritol polyacrylate and 1,6-hexanediol diacrylate.

Commercially available products such as Aronix M-400, Aronix M-460, Aronix M-402, Aronix M-510, and Aronix M-520 (manufactured by Toagosei Co., Ltd.), KAYARAD T-1420, KAYARAD DPHA, KAYARAD DPCA 20, KAYARAD DPCA 30, KAYARAD DPCA 60, and KAYARAD DPCA 120 (manufactured by Nippon Kayaku Co., Ltd.), Viscoat #230, Viscoat #300, Viscoat #802, Viscoat #2500, Viscoat #1000, and Viscoat #1080 (manufactured by Osaka Organic Chemical Industry Co., Ltd.), NK Ester A-BPE-10, NK Ester A-GLY-9E, NK Ester A-9550, and NK Ester A-DPH (manufactured by Shin-Nakamura Chemical Co., Ltd.).

When a polyfunctional (meth)acrylate compound is used, the amount of the polyfunctional (meth)acrylate compound relative to 100 parts by mass of polyimide is preferably 1 to 150 parts by mass, more preferably 20 to 120 parts by mass, and even more preferably 50 to 100 parts by mass.

As described above, in the photosensitive resin composition of the present embodiment, it is considered that an “entangled structure” of the polyimide and the polyfunctional (meth)acrylate is formed by curing; however, it is considered that, by appropriately adjusting the usage amount of the polyfunctional (meth)acrylate compound relative to the polyimide, the polyimide and the polyfunctional (meth)acrylate compound are appropriately entangled and the excess components not involved in the entanglement are reduced. As a result, it is considered that the performance is further improved.

When the photosensitive resin composition includes a polyfunctional (meth)acryl compound, only one polyfunctional (meth)acrylate compound may be included, or two or more polyfunctional (meth)acrylate compounds may be included. In the latter case, it is preferable to use polyfunctional (meth)acrylate compounds having different numbers of functional groups in combination. By using polyfunctional (meth)acrylate compounds having different numbers of functional groups in combination, it is considered that a more complex “entangled structure” is formed and the properties of the cured film are further improved.

Incidentally, among commercially available polyfunctional (meth)acrylate compounds, there are also mixtures of polyfunctional (meth)acrylate compounds having different numbers of functional groups.

In addition, when polyimide and polyfunctional (meth)acryl compounds are used in combination, it is possible to adopt the polymerization reaction of the polyfunctional (meth)acryl compound as the curing mechanism. In principle, this polymerization reaction does not involve dehydration, thus, using polyimide and polyfunctional (meth)acryl compound in combination is advantageous in that shrinkage due to heating is small.

### (Thermal Radical Initiator)

The photosensitive resin composition of the present embodiment may include a thermal radical initiator.

When the photosensitive resin composition contains a polyfunctional (meth)acryl compound as an additive, the use of a thermal radical initiator promotes the polymerization reaction of the polyfunctional (meth)acryl compound, thereby making it possible to further increase the heat resistance of the cured film and/or increase the chemical resistance (resistance to organic solvents and the like) of the cured film.

The thermal radical initiator preferably includes an organic peroxide. Examples of organic peroxides include octanoyl peroxide, lauroyl peroxide, stearoyl peroxide, 1,1,3,3-tetramethylbutylperoxy 2-ethylhexanoate, oxalic acid peroxide, 2,5-dimethyl-2,5-di(2-ethylhexanoylperoxy)hexane, 1-cyclohexyl-1-methylethylperoxy 2-ethylhexanoate, t-hexylperoxy 2-ethylhexanoate, t-butylperoxy 2-ethylhexanoate, m-toluyl peroxide, benzoyl peroxide, benzoyl peroxide, methyl ethyl ketone peroxide, acetyl peroxide, t-butyl hydroperoxide, di-t-butyl peroxide, cumene hydroperoxide, dicumyl peroxide, t-butyl perbenzoate, parachlorobenzoyl peroxide, cyclohexanone peroxide, and the like.

When a thermal radical initiator is used, only one thermal radical initiator may be used, or two or more thermal radical initiators may be used.

When a thermal radical initiator is used, the amount is preferably 0.1 to 30 parts by mass and more preferably 1 to 20 parts by mass with respect to 100 parts by mass of the polyfunctional (meth)acryl compound.

### (Epoxy Compound)

The photosensitive resin composition of the present embodiment may include an epoxy compound. It is considered that the epoxy compound forms chemical bonds through reactions such as reacting with polyimide or reacting with other epoxy compounds. It is possible for the bond formed in this manner to improve the mechanical and physical properties (such as tensile elongation) of the cured film. The epoxy compound is not particularly limited as long as the compound has an epoxy group in the molecule.

Specific examples of epoxy compounds include epoxy resins. Specific examples of epoxy resins include the following. Naturally, the epoxy resin is not limited thereto.

Bisphenol type epoxy resins such as bisphenol A type epoxy resins, bisphenol F type epoxy resins, bisphenol E type epoxy resins, bisphenol S type epoxy resins, hydrogenated bisphenol A type epoxy resins, bisphenol M type epoxy resin (4,4′-(1,3-phenylenediisopridiene) bisphenol type epoxy resin), bisphenol P type epoxy resin (4,4′-(1,4-phenylenediisopridiene) bisphenol type epoxy resin), bisphenol Z type epoxy resin (4,4′-cyclohexydiene bisphenol type epoxy resin), and tetramethyl bisphenol F type epoxy resin; novolac type epoxy resins such as phenol novolac type epoxy resins, brominated phenol novolac type epoxy resins, cresol novolac type epoxy resins, tetraphenol group ethane type novolac type epoxy resins, and novolac type epoxy resins having a condensed ring aromatic hydrocarbon structure; biphenyl type epoxy resins; aralkyl type epoxy resins such as xylylene type epoxy resins and biphenyl aralkyl type epoxy resins; epoxy resins having a naphthalene skeleton, such as naphthylene ether type epoxy resins, naphthol type epoxy resins, naphthalene type epoxy resins, naphthalene diol type epoxy resins, 2-4 functional epoxy type naphthalene resins, binaphthyl type epoxy resins, and naphthalene aralkyl type epoxy resins; anthracene type epoxy resins; phenoxy type epoxy resins; dicyclopentadiene type epoxy resins; norbornene type epoxy resins; adamantane type epoxy resins; heterocyclic epoxy resins such as fluorene type epoxy resins, phosphorus-containing epoxy resins, alicyclic epoxy resins, aliphatic linear epoxy resins, bisphenol A novolac type epoxy resins, bixylenol type epoxy resins, trihydroxyphenylmethane type epoxy resins, stilbene type epoxy resins, tetraphenylolethane type epoxy resins, and triglycidyl isocyanurate; glycidyl amines such as N,N,N′,N′-tetraglycidylmethaxylenediamine, N,N,N′,N′-tetraglycidyl bisaminomethylcyclohexane, and N,N-diglycidyl aniline, or copolymers of glycidyl (meth)acrylate and compounds having an ethylenically unsaturated double bond; epoxy resins having a butadiene structure; diglycidyl ethers of bisphenols; diglycidyl ethers of naphthalenediol; glycidyl ethers of phenols, and the like.

In addition, as the epoxy resin, it is possible to include polyfunctional epoxy resins having three or more functionalities (that is, having three or more epoxy groups in one molecule). More preferably, the polyfunctional epoxy resin has three or more functionalities and 20 or less functionalities.

In addition, examples of the epoxy compound also include a compound having at least one epoxy-containing group and at least one (meth)acryloyl group in one molecule. This compound is preferably a compound having at least one epoxy-containing group at one terminal of the molecule and at least one (meth)acryloyl group at the other terminal. Specific examples include glycidyl (meth)acrylate, 4-hydroxybutyl acrylate glycidyl ether, 3,4-epoxycyclohexylmethyl methacrylate, and the like.

From the viewpoint of further improving storage stability and copper adhesion stability, the epoxy compound of the present embodiment preferably includes a compound having at least one epoxy-containing group and at least one (meth)acryloyl group in one molecule, and more preferably includes 4-hydroxybutyl acrylate glycidyl ether.

When an epoxy compound is used, only one epoxy compound may be used, or two or more epoxy compounds may be used in combination.

When an epoxy compound is used, the amount is, for example, 0.5 to 100 parts by mass, preferably 1 to 50 parts by mass, and more preferably 3 to 20 parts by mass with respect to 100 parts by mass of polyimide.

### (Curing Catalyst)

The photosensitive resin composition of the present embodiment may include a curing catalyst.

When the photosensitive resin composition contains an epoxy compound, using a curing catalyst promotes the polymerization reaction of the epoxy compound and, for example, it is possible to further improve the tensile elongation of the cured film.

Examples of curing catalysts include compounds generally known as a curing catalyst for epoxy resins (often also called curing promoters). Examples of the curing catalyst include diazabicycloalkenes such as 1,8-diazabicyclo[5,4,0]undecene-7, and derivatives thereof; amine-based compounds such as tributylamine and benzyldimethylamine; imidazole compounds such as 2-methylimidazole; organic phosphines such as triphenylphosphine and methyldiphenylphosphine; tetra-substituted phosphonium salts such as tetraphenylphosphonium tetraphenylborate, tetraphenylphosphonium tetrabenzoic acid borate, tetraphenylphosphonium tetranaphthoic acid borate, tetraphenylphosphonium tetranaphthoyloxyborate, tetraphenylphosphonium tetranaphthyloxyborate, and tetraphenylphosphonium 4,4′-sulfonyldiphenolate; triphenylphosphine adducted with benzoquinone, and the like. Among the above, organic phosphines are preferable.

When using a curing catalyst, only one curing catalyst may be used, or two or more curing catalysts may be used.

When a curing catalyst is used, the amount is, for example, 1 to 80 parts by mass, preferably 5 to 50 parts by mass, and more preferably 5 to 30 parts by mass with respect to 100 parts by mass of the epoxy compound.

### (Adhesive Agent)

The photosensitive resin composition of the present embodiment preferably includes an adhesive agent from the viewpoint of further improving the copper adhesion stability.

It is possible for the adhesive agent of the present embodiment to include, for example, one type or two or more types selected from the group consisting of 3-mercapto-1,2,4-triazole, 5-mercapto-4H-1,2,4-triazol-3-ol, 5-mercapto-4-methyl-1,2,4-triazol-3-ol, 3-methylthio-4H-1,2,4-triazole, 3-methylthio-4-methyl-1,2,4-triazole, 3-mercapto-4-methyl-4H-1,2,4-triazole, 3-methylthio-4H-1,2,4-triazole, 5-mercapto-1H-tetrazole, 5-mercapto-1-methyltetrazole, and 5-methylthio-1H-tetrazole.

Among the above, the adhesive agent of the present embodiment preferably includes 3-mercapto-1,2,4-triazole from the viewpoint of further improving the copper adhesion stability.

From the viewpoint of further improving the copper adhesion stability, the adhesive agent of the present embodiment is preferably reacted under conditions of 40 °C or higher and 100 °C or lower for 1 hour or more and 10 hours or less with the epoxy compound of the present embodiment in a state of being dissolved in a solvent to obtain a solution of 5% or more and 50% or less, and then mixed with other components.

From the viewpoint of further improving the copper adhesion stability, the content of the adhesive agent (solid content) of the present embodiment is preferably 1 part by mass or more, more preferably 2 parts by mass or more, and even more preferably 3 parts by mass or more with respect to 100 parts by mass of polyimide, and is preferably 10 parts by mass or less, more preferably 7 parts by mass or less, and even more preferably 5 parts by mass or less.

### (Solvent)

The photosensitive resin composition of the present embodiment preferably includes a solvent. This makes it possible to easily form a photosensitive resin film on a base material (in particular, a base material having a level difference) by a coating method.

The solvent usually includes an organic solvent. The organic solvent is not particularly limited as long as it is possible to dissolve or disperse each of the above-described components and the organic solvent does not substantially chemically react with each of the constituent components.

Examples of organic solvents include acetone, methyl ethyl ketone, toluene, propylene glycol methyl ethyl ether, propylene glycol dimethyl ether, propylene glycol 1-monomethyl ether 2-acetate, diethylene glycol ethyl methyl ether, diethylene glycol monoethyl ether acetate, diethylene glycol monobutyl ether acetate, benzyl alcohol, propylene carbonate, ethylene glycol diacetate, propylene glycol diacetate, propylene glycol monomethyl ether acetate, dipropylene glycol methyl-n-propyl ether, butyl acetate, γ-butyrolactone, methyl lactate, ethyl lactate, butyl lactate, and the like. The above may be used alone or a plurality thereof may be used in combination.

Among the above, the organic solvent of the present embodiment preferably includes one type or two or more types selected from the group consisting of ethyl lactate and γ-butyrolactone.

When the photosensitive resin composition of the present embodiment includes a solvent, the photosensitive resin composition of the present embodiment is usually varnish-like. Since the photosensitive resin composition of the present embodiment is varnish-like, it is possible to form a uniform film by coating. In addition, preferably, the photosensitive resin composition of the present embodiment is varnish-like and at least the polyimide is dissolved in a solvent. As described above, it is possible to increase the solvent solubility of the polyimide by selecting a polyimide with an appropriate chemical structure.

When the non-volatile components in the photosensitive resin composition are the “total solid content”, when a solvent is used, the solvent is preferably used such that the concentration of the total solid content in the photosensitive resin composition is 10% to 50% by mass, and more preferably 20 to 45% by mass. By setting the concentration in this range, it is possible to sufficiently dissolve or disperse each component. In addition, it is possible to ensure good coating properties, which in turn leads to improved flatness during spin coating. Furthermore, it is possible to appropriately control the viscosity of the photosensitive resin composition by adjusting the content of the non-volatile components.

### Other Components

The photosensitive resin composition of the present embodiment may include components other than the components listed, as necessary. Examples of such components include surfactants, antioxidants, fillers such as silica, sensitizers, film-forming agents, and the like.

The lower limit of the glass transition temperature of the cured film of the photosensitive resin composition measured by TMA is, for example, 200 °C or higher, preferably 230 °C or higher, and more preferably 250 °C or higher. This makes it possible to improve the heat resistance of the cured film. The upper limit of the glass transition temperature of the cured film of the photosensitive resin composition is not particularly limited, but is, for example, 400 °C or lower.

From the viewpoint of further improving storage stability, the appearance of the photosensitive resin composition of the present embodiment after being left to stand at 23 °C for 24 hours is preferably free of precipitation and more preferably free of precipitation and turbidity.

In addition, the 90° peel strength of the photosensitive resin composition measured according to the procedure described in the Examples is, for example, 0.9 N/cm or more, preferably 1.0 N/cm or more, and more preferably 1.6 N/cm or more. This makes it possible to realize a resin film having excellent copper adhesion in the actual processes.

The upper limit value of the 90° peel strength of the photosensitive resin composition of the present embodiment is not particularly limited, but is, for example, 10.0 N/cm or less, and may be 7.0 N/cm or less, or may be 5.0 N/cm or less.

From the viewpoint of further improving the copper adhesion stability, the 90° peel strength fluctuation number of the photosensitive resin composition of the present embodiment measured according to the procedure described in the Examples is preferably 70% or less, more preferably 60% or less, even more preferably 50% or less, even more preferably 45% or less, even more preferably 40% or less, and even more preferably 35% or less.

The lower limit value of the 90° peel strength fluctuation number of the photosensitive resin composition of the present embodiment is not particularly limited, but is, for example, 0% or more, and may be 3% or more, or may be 5% or more.

In addition, the viscosity of the photosensitive resin composition is defined as η₀ and the viscosity of the photosensitive resin composition after leaving the photosensitive resin composition to stand for 7 days at 23 °C is defined as η₁.

The value of η₁/η₀ is preferably 1.5 or less, more preferably 1.3 or less, and even more preferably 1.1 or less.

The value of η₁/η₀ is ideally 1, but depending on various conditions, may be less than 1, for example, 0.9.

In addition, from the viewpoint of further improving storage stability, the value of η₁/η₀ of the photosensitive resin composition of the present embodiment is even more preferably 1.08 or less, even more preferably 1.05 or less, and even more preferably 1.03 or less.

The viscosity in the present embodiment is a value obtained by measuring the viscosity of the photosensitive resin composition immediately after blending, using an E-type viscometer.

An example of the method for producing a photosensitive resin composition of the present embodiment includes a step of obtaining a photosensitive resin composition by dissolving the polyimide (A) having an imide ring structure in the molecule and the photosensitizer (B) in a solvent.

In the step of obtaining the photosensitive resin composition, the method for producing a photosensitive resin composition includes a step of adjusting the moisture content in the photosensitive resin composition measured by the Karl Fischer method to 0.30% by mass or more and 10% by mass or less (predetermined range). It is possible to adopt the above-described numerical ranges as the predetermined range of the moisture content in the photosensitive resin composition. The method for adjusting the moisture content is not particularly limited.

The method for producing a photosensitive resin composition preferably includes one or more repetitions of a step of measuring the moisture content in the photosensitive resin composition by the Karl Fischer method and determining whether the moisture content is within the predetermined range. When the moisture content is below the predetermined range, moisture is added to adjust the moisture content.

The moisture may be moisture included in each component, moisture included in the solvent, or a water solvent or the like. It is preferable to adopt a solvent that dissolves moisture.

An example of moisture included in a component is an aqueous solution including the silane coupling agent (C) and water. In this case, in the step of obtaining the photosensitive resin composition, the method for producing a photosensitive resin composition may include a step of preparing an aqueous solution including the silane coupling agent (C) and water and adding the aqueous solution to the photosensitive resin composition. The timing of adding the aqueous solution to the photosensitive resin composition is not particularly limited, but may be before or after adding the above-described component (A) and component (B) to the solvent, or a mixed liquid in which these components are mixed may be added to the solvent. The aqueous solution may be added to the solvent once or twice or more times.

### <Method for Producing Electronic Device and Electronic Device>

It is possible for the method for producing an electronic device of the present embodiment to include
a film forming step of forming a photosensitive resin film on a substrate using the above-described photosensitive resin composition,
a light exposure step of exposing the photosensitive resin film to light, and
a development step of developing the light-exposed photosensitive resin film.

In addition, the method for producing an electronic device of the present embodiment preferably includes a thermal curing step of heating and curing the light-exposed photosensitive resin film after the above-described development step. This makes it possible to obtain a cured film having more than sufficient heat resistance.

In this manner, it is possible to produce an electronic device provided with a resin film formed of the cured film of the photosensitive resin composition of the present embodiment.

With reference to the drawings, a more detailed description will be given below of the method for producing an electronic device of the present embodiment, the structure of an electronic device provided with a cured product of the photosensitive resin composition of the present embodiment, and the like.

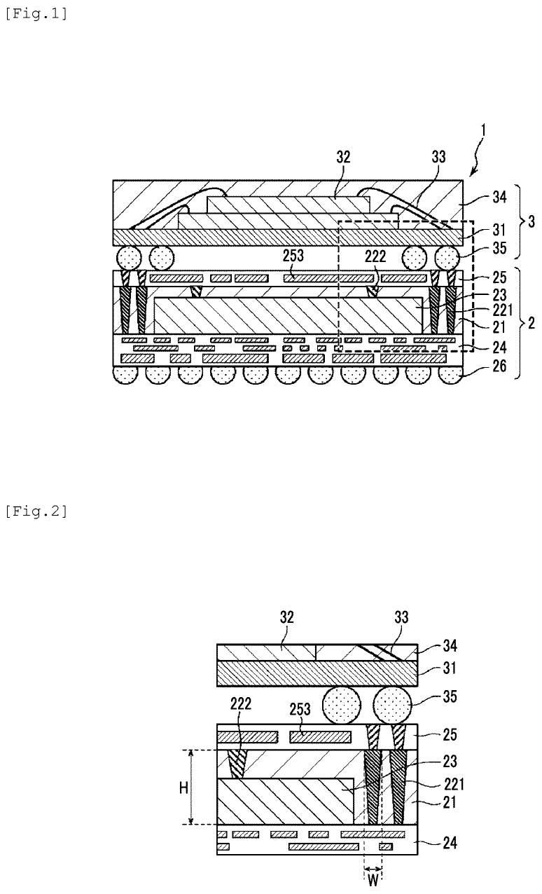

FIG. 1 is a longitudinal cross-sectional view showing an example of the electronic device according to the present embodiment.

In addition, FIG. 2 is a partial enlarged view of the region surrounded by the dashed line in FIG. 1.

In the following description, the upper side in FIG. 1 is referred to as “upper” and the lower side is referred to as “lower”.

An electronic device 1 shown in FIG. 1 has a so-called package-on-package structure provided with a through electrode substrate 2 and a semiconductor package 3 mounted thereon.

The through electrode substrate 2 is provided with an insulating layer 21, a plurality of through wires 221 penetrating the insulating layer 21 from the upper surface to the lower surface, a semiconductor chip 23 embedded inside the insulating layer 21, a lower wiring layer 24 provided on the lower surface of the insulating layer 21, an upper wiring layer 25 provided on the upper surface of the insulating layer 21, and solder bumps 26 provided on the lower surface of the lower wiring layer 24.

The semiconductor package 3 is provided with a package substrate 31, a semiconductor chip 32 mounted on the package substrate 31, a bonding wire 33 electrically connecting the semiconductor chip 32 and the package substrate 31, a sealing layer 34 in which the semiconductor chip 32 and the bonding wire 33 are embedded, and solder bumps 35 provided on the lower surface of the package substrate 31.

Then, the semiconductor package 3 is laminated on the through electrode substrate 2. Due to this, the solder bumps 35 of the semiconductor package 3 are electrically connected to the upper wiring layer 25 of the through electrode substrate 2.

It is possible to easily reduce the height of the electronic device 1 since there is no need to use a thick substrate such as an organic substrate including a core layer in the through electrode substrate 2. For this reason, it is possible to also contribute to the miniaturization of electronic equipment incorporating the electronic device 1.

In addition, since the through electrode substrate 2 and the semiconductor package 3, which are provided with different semiconductor chips, are laminated, it is possible to increase the packaging density per unit area. For this reason, it is possible to achieve both miniaturization and high performance.

A more detailed description will be given below of the through electrode substrate 2 and the semiconductor package 3.

The lower wiring layer 24 and upper wiring layer 25 provided in the through electrode substrate 2 shown in FIG. 2 each include an insulating layer, a wiring layer, through wires, and the like. Due to this, the lower wiring layer 24 and the upper wiring layer 25 include wiring inside and on the surface and are electrically connected to each other through the through wires 221 that penetrate the insulating layer 21.

The wiring layer included in the lower wiring layer 24 is connected to the semiconductor chip 23 and the solder bumps 26. For this reason, the lower wiring layer 24 functions as a rewiring layer of the semiconductor chip 23 while the solder bumps 26 function as external terminals of the semiconductor chip 23.

The through wires 221 shown in FIG. 2 are provided to penetrate the insulating layer 21, as described above. Due to this, the lower wiring layer 24 and the upper wiring layer 25 are electrically connected and it is possible to laminate the through electrode substrate 2 and the semiconductor package 3, thereby making it possible to achieve high functionality in the electronic device 1.

A wiring layer 253 included in the upper wiring layer 25 shown in FIG. 2 is connected to the through wire 221 and the solder bumps 35. For this reason, the upper wiring layer 25 is electrically connected to the semiconductor chip 23 and functions as a rewiring layer for the semiconductor chip 23 and also functions as an interposer between the semiconductor chip 23 and the package substrate 31. It is possible to use the cured film of the photosensitive resin composition of the present embodiment to form an insulating layer of the rewiring layer.

According to the present embodiment, it is possible to realize an electronic device provided with the semiconductor chip 23 and a rewiring layer (the upper wiring layer 25) provided on the surface of the semiconductor chip 23, in which the insulating layer in the rewiring layer is formed of a cured product of the photosensitive resin composition of the present embodiment.

The through wires 221 penetrate the insulating layer 21, thereby providing an effect of reinforcing the insulating layer 21. For this reason, even when the mechanical strength of the lower wiring layer 24 or the upper wiring layer 25 is low, it is possible to avoid a decrease in the mechanical strength of the through electrode substrate 2 as a whole. As a result, it is possible to achieve further thinning of the lower wiring layer 24 and the upper wiring layer 25 and to further reduce the height of the electronic device 1.

In addition, the electronic device 1 shown in FIG. 1 is also provided with through wires 222 provided to penetrate the insulating layer 21 positioned on the upper surface of the semiconductor chip 23 in addition to the through wires 221. Due to this, it is possible to achieve an electrical connection between the upper surface of the semiconductor chip 23 and the upper wiring layer 25.

The insulating layer 21 is provided to cover the semiconductor chip 23. Due to this, the effect of protecting the semiconductor chip 23 is improved. As a result, it is possible to improve the reliability of the electronic device 1. In addition, the obtained electronic device 1 is able to be easily applied in a mounting set-up such as the package-on-package structure according to the present embodiment.

The diameter W (see FIG. 2) of the through wires 221 is not particularly limited, but is preferably approximately 1 to 100 μm and more preferably approximately 2 to 80 μm. Due to this, it is possible to ensure the conductivity of the through wires 221 without impairing the mechanical properties of the insulating layer 21.

The semiconductor package 3 shown in FIG. 1 may be a package of any shape. Examples thereof include Quad Flat Package (QFP), Small Outline Package (SOP), Ball Grid Array (BGA), Chip Size Package (CSP), Quad Flat Non-leaded Package (QFN), Small Outline Non-leaded Package (SON), Lead Flame BGA (LF-BGA), and the like.

The arrangement of the semiconductor chips 32 is not particularly limited, but, as an example, a plurality of the semiconductor chips 32 are laminated in FIG. 1. Due to this, an increase in the packaging density is achieved. The plurality of semiconductor chips 32 may be arranged side by side in the planar direction, or may be arranged side by side in the planar direction while being laminated in the thickness direction.

The package substrate 31 may be any substrate, for example, a substrate including an insulating layer, a wiring layer, a through wire, or the like, which are not shown. It is possible to electrically connect the solder bumps 35 and the bonding wires 33 through the through wires.

The sealing layer 34 is formed of, for example, a known sealing resin material. By providing the sealing layer 34 in this manner, it is possible to protect the semiconductor chips 32 and the bonding wires 33 from external forces and the external environment.

The semiconductor chip 23 provided in the through electrode substrate 2 and the semiconductor chip 32 provided in the semiconductor package 3 are arranged close to each other. Due to this, it is possible to gain benefits such as faster communication and lower loss. From this viewpoint, for example, when one of the semiconductor chip 23 and the semiconductor chip 32 is a computing element such as a Central Processing Unit (CPU), a Graphics Processing Unit (GPU), or an Application Processor (AP), and the other is a storage element such as a Dynamic Random Access Memory (DRAM) or flash memory, or the like, it is possible to arrange these elements to be close to each other in the same device. Due to this, it is possible to realize the electronic device 1 that achieves both increased functionality and miniaturization.

Next, a description will be given of the method for producing the electronic device 1 shown in FIG. 1.

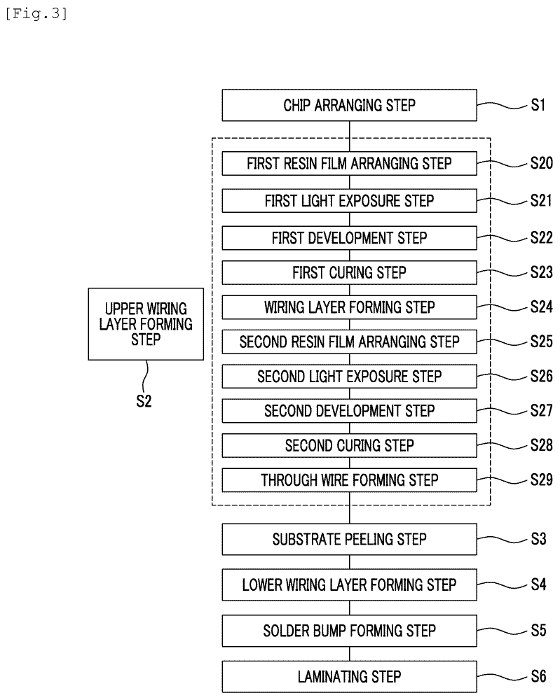

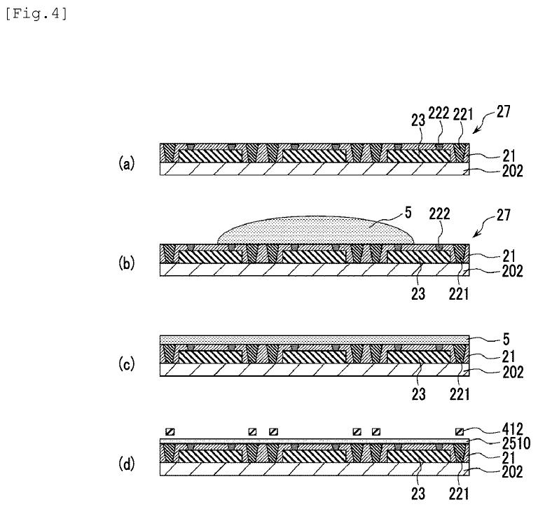

FIG. 3 is a step diagram showing the method for producing the electronic device 1 shown in FIG. 1. In addition, FIG. 4 to FIG. 6 are each diagrams for illustrating the method for producing the electronic device 1 shown in FIG. 1.

The method for producing the electronic device 1 includes a chip arranging step S1 of obtaining the insulating layer 21 for embedding the semiconductor chip 23 and the through wires 221 and 222 provided on the substrate 202, an upper wiring layer forming step S2 of forming the upper wiring layer 25 on the insulating layer 21 and the semiconductor chip 23, a substrate peeling step S3 of peeling the substrate 202, a lower wiring layer forming step S4 of forming the lower wiring layer 24, a solder bump forming step S5 of forming the solder bumps 26 and obtaining the through electrode substrate 2, and a laminating step S6 of laminating the semiconductor package 3 on the through electrode substrate 2.

Among the above, the upper wiring layer forming step S2 includes a first resin film arranging step S20 of arranging a photosensitive resin varnish 5 (a varnish-like photosensitive resin composition) on the insulating layer 21 and the semiconductor chip 23 to obtain a photosensitive resin layer 2510, a first light exposure step S21 of conducting a light exposure treatment on the photosensitive resin layer 2510, a first development step S22 of conducting a development treatment on the photosensitive resin layer 2510, a first curing step S23 of conducting a curing treatment on the photosensitive resin layer 2510, a wiring layer forming step S24 of forming the wiring layer 253, a second resin film arranging step S25 of arranging the photosensitive resin varnish 5 on the photosensitive resin layer 2510 and the wiring layer 253 to obtain a photosensitive resin layer 2520, a second light exposure step S26 of conducting a light exposure treatment on the photosensitive resin layer 2520, a second development step S27 of conducting a development treatment on the photosensitive resin layer 2520, a second curing step S28 of conducting a curing treatment on the photosensitive resin layer 2520, and a through wire forming step S29 of forming a through wire 254 in an opening 424 (through hole).

A description will be given below of each step in order. The following production method is an example and is not intended to be limiting.

### [1] Chip Arranging Step S1

First, as shown in FIG. 4(a), a chip-embedded structure 27 is prepared, which is provided with the substrate 202, the semiconductor chip 23 and the through wires 221 and 222 provided on the substrate 202, and the insulating layer 21 provided to embed the semiconductor chip 23 and the through wires 221 and 222.

The constituent materials of the substrate 202 are not particularly limited, but examples thereof include metal materials, glass materials, ceramic materials, semiconductor materials, organic materials, and the like. In addition, a semiconductor wafer such as a silicon wafer, a glass wafer, or the like may also be used as the substrate 202.

The semiconductor chip 23 is adhered onto the substrate 202. In this production method, as an example, a plurality of the semiconductor chips 23 are arranged side by side on the same substrate 202 while being spaced apart from each other. The plurality of semiconductor chips 23 may be of the same type as each other or different types to each other. In addition, the substrate 202 and the semiconductor chip 23 may also be fixed to each other through an adhesive layer (not shown) such as a die-attach film.

As necessary, an interposer (not shown) may be provided between the substrate 202 and the semiconductor chip 23. The interposer functions as, for example, a rewiring layer for the semiconductor chip 23. Accordingly, the interposer may be provided with pads (not shown) for electrically connecting to electrodes of the semiconductor chip 23, which will be described below. Due to this, it is possible to convert the pad spacing and arrangement pattern of the semiconductor chip 23 and to increase the design freedom of the electronic device 1.

For example, an inorganic substrate such as a silicon substrate, a ceramic substrate, or a glass substrate, an organic substrate such as a resin substrate, or the like may be used as the interposer.

The insulating layer 21 may be, for example, a resin film (organic insulating layer) including a thermosetting resin or a thermoplastic resin, such as the examples listed as components of the photosensitive resin composition, or may be a normal sealing material used in the technical field of semiconductors.

Examples of the constituent materials forming the through wires 221 and 222 include copper or a copper alloy, aluminum or an aluminum alloy, gold or a gold alloy, silver or a silver alloy, nickel or a nickel alloy, and the like.

The chip-embedded structure 27 produced by a method different from the above may be prepared.

### [2] Upper Wiring Layer Forming Step S2

Next, the upper wiring layer 25 is formed on the insulating layer 21 and on the semiconductor chip 23.

### [2-1] First Resin Film Arranging Step S20

First, as shown in FIG. 4(b), the photosensitive resin varnish 5 is coated (arranged) on the insulating layer 21 and on the semiconductor chip 23. Due to this, a liquid coating of the photosensitive resin varnish 5 is obtained as shown in FIG. 4(c). The photosensitive resin varnish 5 is the photosensitive resin composition of the present embodiment.

The photosensitive resin varnish 5 is coated using, for example, a spin coater, a bar coater, a spray device, an ink jet device, or the like.

The viscosity of the photosensitive resin varnish 5 is not particularly limited, but is 10 cP to 6000 cP, preferably 20 cP to 5000 cP, and more preferably 30 cP to 4000 cP. By setting the viscosity of the photosensitive resin varnish 5 within the above range, it is possible to form the photosensitive resin layer 2510 to be thinner (refer to FIG. 4(d)). As a result, it is possible to make the upper wiring layer 25 thinner, making it easier to achieve thinning of the electronic device 1.

The viscosity of the photosensitive resin varnish 5 is, for example, a value measured using a cone-plate type viscometer (TV-25, manufactured by Toki Sangyo Co., Ltd.) under the condition of a rotation speed of 100 rpm.

Next, the liquid coating of the photosensitive resin varnish 5 is dried. Due to this, the photosensitive resin layer 2510 shown in FIG. 4(d) is obtained.

The drying conditions of the photosensitive resin varnish 5 are not particularly limited, but may be, for example, conditions of heating at a temperature of 80 to 150 °C for 1 to 60 minutes.

In this step, instead of the process of coating the photosensitive resin varnish 5, a process of arranging a photosensitive resin film formed into a film from the photosensitive resin varnish 5 may be adopted. The photosensitive resin film is the photosensitive resin composition of the present embodiment and is a resin film having photosensitivity.

The photosensitive resin film is produced, for example, by coating the photosensitive resin varnish 5 on a base such as a carrier film using various coating devices, and then drying the obtained coated film.

After the photosensitive resin layer 2510 is formed in this manner, a pre-exposure heating treatment is conducted on the photosensitive resin layer 2510 as necessary. By conducting the pre-exposure heating treatment, the molecules included in the photosensitive resin layer 2510 are stabilized such that it is possible to stabilize the reaction in the first light exposure step S21 described below. In addition, on the other hand, by heating under the heating conditions described below, it is possible to minimize the adverse effect of heating on the photoacid generator.

The temperature of the pre-exposure heating treatment is preferably 70 to 130 °C, more preferably 75 to 120 °C, and even more preferably 80 to 110 °C. When the temperature of the pre-exposure heating treatment is below the lower limit value, there is a concern that the purpose of stabilizing the molecules through the pre-exposure heating treatment may not be achieved. Meanwhile, when the temperature of the pre-exposure heating treatment is above the upper limit value, the movement of the photoacid generator becomes excessively active and there is a concern that the patterning processing accuracy may be reduced due to the effect of making it difficult to generate acid even when irradiated with light in the first light exposure step S21 described below becoming widespread.

The time of the pre-exposure heating treatment is appropriately set according to the temperature of the pre-exposure heating treatment and is preferably 1 to 10 minutes at the temperature, more preferably 2 to 8 minutes, and even more preferably 3 to 6 minutes. When the time of the pre-exposure heating treatment is below the lower limit value, the heating time is insufficient such that there is a concern that the purpose of stabilizing the molecules through the pre-exposure heating treatment may not be achieved. Meanwhile, when the time of the pre-exposure heating treatment exceeds the upper limit value, the heating time is excessively long such that, even when the temperature of the pre-exposure heating treatment is within the above range, there is a concern that the action of the photoacid generator may be inhibited.

The atmosphere in the heating treatment is not particularly limited. The atmosphere may be an inert gas atmosphere or a reducing gas atmosphere, but is preferably atmospheric air in consideration of work efficiency, and the like.

The atmospheric pressure is not particularly limited. The atmospheric pressure may be reduced pressure or increased pressure, but is preferably normal pressure in consideration of work efficiency, and the like. Normal pressure refers to a pressure of approximately 30 to 150 kPa, preferably atmospheric pressure.

### [2-2] First Light Exposure Step S21

Next, a light exposure treatment is conducted on the photosensitive resin layer 2510.

First, as shown in FIG. 4(d), a mask 412 is arranged on a predetermined region of the photosensitive resin layer 2510. Then, light (active radiation) is irradiated through the mask 412. Due to this, the photosensitive resin layer 2510 is subjected to a light exposure treatment according to the pattern of the mask 412.

FIG. 4(d) illustrates a case in which the photosensitive resin layer 2510 has so-called negative-type photosensitivity. In this example, the regions of the photosensitive resin layer 2510 that correspond to the light-shielding parts of the mask 412 dissolve in the developer.

Meanwhile, in the region that corresponds to the transparent part of the mask 412, active chemical species are generated from the photocationic polymerization initiator. The active chemical species act as a catalyst for the curing reaction.

The amount of light exposure in the light exposure treatment is not particularly limited. 100 to 2000 mJ/cm² is preferable and 200 to 1000 mJ/cm² is more preferable. Due to this, it is possible to suppress underexposure and overexposure in the photosensitive resin layer 2510. As a result, it is possible to finally realize high patterning accuracy.

Thereafter, as necessary, a post-exposure heating treatment is conducted on the photosensitive resin layer 2510.

The temperature of the post-exposure heating treatment is not particularly limited. 50 to 150 °C is preferable, 50 to 130 °C is more preferable, 55 to 120 °C is even more preferable, and 60 to 110 °C is particularly preferable. By conducting the post-exposure heating treatment at such a temperature, the catalytic action of the generated acid is sufficiently enhanced and it is possible to sufficiently react the thermosetting resin in a shorter time. By setting the temperature to be within the above range, it is possible to suppress a decrease in the patterning processing accuracy due to the promotion of acid diffusion.

By setting the temperature of the post-exposure heating treatment to the above lower limit value or more, it is possible to increase the reaction rate of the thermosetting resin and to improve the productivity. Meanwhile, by setting the temperature of the post-exposure heating treatment to the above upper limit value or less, it is possible to suppress the deterioration of the patterning processing accuracy due to the promotion of acid diffusion.

The time of the post-exposure heating treatment is appropriately set according to the temperature of the post-exposure heating treatment. The time at the above temperature is preferably 1 to 30 minutes, more preferably 2 to 20 minutes, and even more preferably 3 to 15 minutes. By conducting the post-exposure heating treatment for such a time, it is possible to sufficiently react the thermosetting resin and to inhibit the diffusion of acid and suppress the deterioration of the patterning processing accuracy.

The atmosphere in the post-exposure heating treatment is not particularly limited. The atmosphere may be an inert gas atmosphere or a reducing gas atmosphere, but is preferably atmospheric air in consideration of work efficiency, and the like.

The atmospheric pressure of the post-exposure heating treatment is not particularly limited. The atmospheric pressure may be reduced pressure or increased pressure, but is preferably normal pressure in consideration of work efficiency, and the like. Due to this, it is possible to conduct the pre-exposure heating treatment relatively easily. Normal pressure refers to a pressure of approximately 30 to 150 kPa, preferably atmospheric pressure.

### [2-3] First Development Step S22

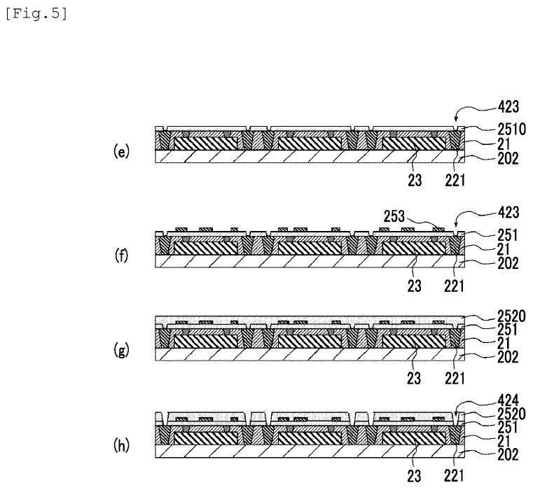

Next, a development treatment is conducted on the photosensitive resin layer 2510. Due to this, an opening 423 penetrating the photosensitive resin layer 2510 is formed in the region corresponding to the light-shielding part of the mask 412 (refer to FIG. 5(e)).

Examples of the developer include an organic solvent-based developer, a water-soluble developer, and the like. In the present embodiment, the developer preferably contains an organic solvent. More specifically, the developer is preferably a developer in which the main component is an organic solvent (a developer in which 95% by mass or more of the components are the organic solvent). By developing with a developer containing an organic solvent, it is possible to inhibit swelling of the pattern caused by the developer or the like compared to a case of developing with an alkaline developer (water-based). In other words, it is easier to obtain a finer pattern.

Specific examples of organic solvents usable as the developer include ketone-based solvents such as cyclopentanone, ester-based solvents such as propylene glycol monomethyl ether acetate (PGMEA) and butyl acetate, ether-based solvents such as propylene glycol monomethyl ether, and the like.

As the developer, an organic solvent developer that is formed of only organic solvents and does not include any impurities other than impurities that are inevitably included may be used. Inevitably included impurities include metal elements and moisture, but from the viewpoint of preventing contamination of electronic devices or the like, having as few inevitably included impurities as possible is better.

The method for bringing the developer into contact with the photosensitive resin layer 2510 is not particularly limited. It is possible to use generally known immersion methods, paddle methods, spray methods, and the like, as appropriate.

The time for the development step is usually in the range of approximately 5 to 300 seconds, preferably approximately 10 to 120 seconds, and the time is appropriately adjusted based on the film thickness of the resin film, the shape of the pattern to be formed, and the like.

### [2-4] First Curing Step S23

After the development treatment, a curing treatment (post-development heating treatment) is conducted on the photosensitive resin layer 2510.

The conditions for the curing treatment are not particularly limited, but are set to a heating temperature of approximately 160 to 250 °C and a heating time of approximately 30 to 240 minutes. Due to this, it is possible to cure the photosensitive resin layer 2510 while inhibiting the thermal effects on the semiconductor chip 23, and to obtain the organic insulating layer 251.

### [2-5] Wiring Layer Forming Step S24

Next, the wiring layer 253 is formed on the organic insulating layer 251 (refer to FIG. 5(f)). The wiring layer 253 is formed by, for example, obtaining a metal layer using a vapor phase deposition method such as a sputtering method or a vacuum deposition method, and then carrying out patterning using a photolithography method and an etching method.

Prior to the formation of the wiring layer 253, a surface modification treatment such as a plasma treatment may be conducted.

### [2-6] Second Resin Film Arranging Step S25

Next, as shown in FIG. 5(g), the photosensitive resin layer 2520 is obtained in the same manner as in the first resin film arranging step S20. The photosensitive resin layer 2520 is arranged so as to cover the wiring layer 253.

Thereafter, as necessary, a pre-exposure heating treatment is conducted on the photosensitive resin layer 2520. The treatment conditions are, for example, the conditions described in the first resin film arranging step S20.

### [2-7] Second Light Exposure Step S26

Next, a light exposure treatment is conducted on the photosensitive resin layer 2520. The treatment conditions are, for example, the conditions described in the first light exposure step S21.

Thereafter, as necessary, a post-exposure heating treatment is conducted on the photosensitive resin layer 2520. The treatment conditions are, for example, the conditions described in the first light exposure step S21.

### [2-8] Second Development Step S27

Next, a development treatment is conducted on the photosensitive resin layer 2520. The treatment conditions are, for example, the conditions described in the first development step S22. Due to this, the opening 424 penetrating the photosensitive resin layers 2510 and 2520 is formed (refer to FIG. 5(h)).

### [2-9] Second Curing Step S28

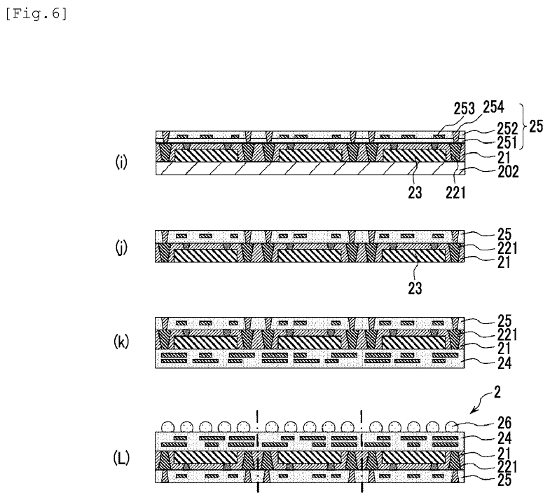

After the development treatment, a curing treatment (post-development heating treatment) is conducted on the photosensitive resin layer 2520. The curing conditions are, for example, the conditions described in the first curing step S23. Due to this, the photosensitive resin layer 2520 is cured to obtain an organic insulating layer 252 (refer to FIG. 6(i)).

In the present embodiment, the upper wiring layer 25 has two layers, which are the organic insulating layer 251 and the organic insulating layer 252, but the upper wiring layer 25 may have three or more layers. In this case, after the second curing step S28, the series of steps from the wiring layer forming step S24 to the second curing step S28 may be repeatedly added.

### [2-10] Through Wire Forming Step S29

Next, the through wire 254 shown in FIG. 6(i) is formed with respect to the opening 424.

A known method may be used to form the through wire 254, for example, the following method.

First, a seed layer, which is not shown, is formed on the organic insulating layer 252. The seed layer is formed on the inner surfaces (side surface and bottom surface) of the opening 424 and on the upper surface of the organic insulating layer 252.

A copper seed layer may be used as the seed layer, for example. In addition, the seed layer may be formed by, for example, a sputtering method.

The seed layer may be formed of the same metal as the through wire 254 to be formed, or may be formed of a different metal.

Next, a resist layer, which is not shown, is formed on the seed layer, which is not shown, in the regions other than the opening 424. Then, using this resist layer as a mask, the opening 424 is filled with a metal. For example, an electrolytic plating method is used for this filling. The metal to be filled may be, for example, copper or a copper alloy, aluminum or an aluminum alloy, gold or a gold alloy, silver or a silver alloy, nickel or a nickel alloy, or the like. In this manner, the conductive material is embedded in the opening 424 and the through wire 254 is formed.

Next, the resist layer, which is not shown, is removed. Furthermore, the seed layer, which is not shown, on the organic insulating layer 252 is removed. For example, it is possible to use a flash etching method for the removal.

The location where the through wire 254 is formed is not limited to the position shown in the figure.

### [3] Substrate Peeling Step S3

Next, as shown in FIG. 6(j), the substrate 202 is peeled off. This exposes the lower surface of the insulating layer 21 to light.

### [4] Lower Wiring Layer Forming Step S4

Next, as shown in FIG. 6(k), the lower wiring layer 24 is formed on the lower surface side of the insulating layer 21. The lower wiring layer 24 may be formed by any method, for example, in the same manner as the upper wiring layer forming step S2 described above.

The lower wiring layer 24 formed in this manner is electrically connected to the upper wiring layer 25 through the through wires 221.

### [5] Solder Bump Forming Step S5

Next, as shown in FIG. 6(L), the solder bumps 26 are formed on the lower wiring layer 24. In addition, a protective film such as a solder resist layer may be formed on the upper wiring layer 25 and the lower wiring layer 24 as necessary.

In this manner, the through electrode substrate 2 is obtained.

It is possible to divide the through electrode substrate 2 shown in FIG. 6(L) into a plurality of regions. Accordingly, for example, by dividing the through electrode substrate 2 along the dot-dash line shown in FIG. 6(L), it is possible to efficiently produce a plurality of the through electrode substrates 2. For the dividing, it is possible to use a diamond cutter or the like, for example.

### [6] Laminating Step S6

Next, the semiconductor package 3 is arranged on the divided through electrode substrate 2. Due to this, the electronic device 1 shown in FIG. 1 is obtained.

It is possible to apply this method for producing the electronic device 1 to a wafer-level process or a panel-level process using a large-area substrate. Due to this, it is possible to improve the production efficiency of the electronic device 1 and achieve cost reductions.

Embodiments of the present invention are described above, but these are merely examples of the present invention and it is possible to adopt various configurations other than the configurations described above. In addition, the present invention is not limited to the above-described embodiments and modifications, improvements, and the like within a range in which it is possible to achieve the object of the present invention are included in the present invention.

### EXAMPLES

A detailed description will be given of the present invention below with reference to Examples, but the present invention is not limited by the description of these Examples.

### Synthesis of Raw Materials

### Synthesis of Polyimide Resin (A-1)

272.2 g (0.85 mol) of 2,2′-bis(trifluoromethyl)benzidine, 355.4 g (0.80 mol) of 4,4′-(hexafluoroisopropylidene)diphthalic anhydride, 62.0 g (0.20 mol) of 4,4′-oxydiphthalic dianhydride, and 2299 g of GBL were added to a 5 L separable flask provided with a stirrer and a cooling tube, and subjected to a polymerization reaction at room temperature for 16 hours in a nitrogen atmosphere. Subsequently, the reaction liquid temperature was raised to 180 °C in an oil bath, a reaction was carried out for 3 hours, and then the result was cooled to room temperature to prepare a polyimide resin solution.

Subsequently, the reaction liquid was added dropwise to a mixed solution of isopropanol/water=4/7 while stirring, and a resin solid was precipitated. The obtained solid was roughly filtered and then washed with isopropanol/water=4/7 to obtain a white solid polyimide. The obtained white solid was vacuum dried at 200 °C to obtain a polyimide resin (A-1) having an imide ring structure.

The weight-average molecular weight (Mw) of the resin (A-1) according to GPC measurement was 38,000. In addition, the imidization rate of the resin analyzed by ¹H-NMR was 95% or more.

The weight-average molecular weight (Mw) was determined by performing gel permeation chromatography (GPC) measurement of the polyimide resin using THF as the solvent, under conditions of a measurement temperature of 40 °C and a sample concentration of 0.5 wt %, and then using the polystyrene equivalent value calculated from the calibration curve of standard polystyrene (PS) obtained by GPC measurement under the same conditions.

The imidization rate was determined by measuring the ¹H-NMR spectrum of the polyimide resin and using the calculation formula {A_{IM}/(A_{IM}+A_{AM})}×100(%) where A_{AM} is the area of the peaks corresponding to the amide groups in the measured ¹H-NMR spectrum and A_{IM} is the area of the peaks corresponding to the imide ring groups.

### Synthesis of Polyimide Resin (A-2)

144.1 g (0.45 mol) of 2,2′-bis(trifluoromethyl)benzidine, 113.0 g (0.40 mol) of 4,4′-diamino-3,3′-diethyl-5,5′-dimethyldiphenylmethane, 444.2 g (1.00 mol) of 4,4′-(hexafluoroisopropylidene)diphthalic anhydride, and 2338 g of GBL were added to a 5 L separable flask provided with a stirrer and a cooling tube and subjected to a polymerization reaction at room temperature for 16 hours in a nitrogen atmosphere. Subsequently, the reaction liquid temperature was raised to 180 °C in an oil bath, a reaction was carried out for 3 hours, and then the result was cooled to room temperature to prepare a polyimide resin solution.

Subsequently, the reaction liquid was added dropwise to a mixed solution of isopropanol/water=4/7 while stirring, and a resin solid was precipitated. The obtained solid was roughly filtered and then washed with isopropanol/water=4/7 to obtain a white solid polyimide. The obtained white solid was vacuum dried at 200 °C to obtain a polyimide resin (A-2) having acid anhydride groups at the terminals.

The weight-average molecular weight (Mw) of the resin (A-2) according to GPC measurement was 40,000. In addition, the imidization rate of the resin analyzed by ¹H-NMR was 95% or more.

### Synthesis of Polyimide Resin (A-3)

304.2 g (0.95 mol) of 2,2′-bis(trifluoromethyl)benzidine, 355.4 g (0.80 mol) of 4,4′-(hexafluoroisopropylidene)diphthalic anhydride, 62.0 g (0.20 mol) of 4,4′-oxydiphthalic dianhydride, and 2406 g of GBL were added to a 5 L separable flask provided with a stirrer and a cooling tube, and subjected to a polymerization reaction at room temperature for 16 hours in a nitrogen atmosphere. Subsequently, the reaction liquid temperature was raised to 180 °C in an oil bath, a reaction was carried out for 3 hours, and then the result was cooled to room temperature to prepare a polyimide resin solution.

Subsequently, the reaction liquid was added dropwise to a mixed solution of isopropanol/water=4/7 while stirring, and a resin solid was precipitated. The obtained solid was roughly filtered and then washed with isopropanol/water=4/7 to obtain a white solid polyimide. The obtained white solid was vacuum dried at 200 °C to obtain a polyimide resin (A-3) having an imide ring structure.

The weight-average molecular weight (Mw) of the resin (A-3) according to GPC measurement was 83,000. In addition, the imidization rate of the resin analyzed by ¹H-NMR was 95% or more.

### Synthesis of Polyimide Precursor Resin (A-4)

428 g of γ-butyrolactone, 155.11 g of 4,4′-oxydiphthalic dianhydride, and 130.14 g of 2-hydroxyethyl methacrylate were placed in a 2 L separable flask, and the components in the flask were stirred at room temperature until completely dissolved. Subsequently, 79.1 g of pyridine was added while stirring at room temperature and the mixture was further stirred at room temperature for 16 hours.

While the solution obtained as above was cooled and stirred under ice cooling, a solution in which 206.3 g of dicyclohexylcarbodiimide was dissolved in 206 g of γ-butyrolactone was added to the solution over 30 minutes. Subsequently, 120.1 g of 4,4′-diaminodiphenyl ether and 240 g of γ-butyrolactone were added thereto and stirring was continued at room temperature for a further 2 hours.

After the reaction was completed, 30 g of ethanol was added thereto and stirred for 1 hour. Thereafter, 400 g of γ-butyrolactone was added thereto and further stirred, and the precipitate that occurred was removed by filtration. Due to this, a reaction liquid of polyamic acid ester was obtained.

The obtained reaction liquid was added dropwise to a large amount of a 30% by mass aqueous methanol solution at room temperature while stirring, causing the resin to precipitate. The obtained precipitate was collected by filtration and vacuum dried at 50 °C for 16 hours to obtain a polyamic acid resin (A-4).

The weight-average molecular weight (Mw) of the resin (A-4) according to GPC measurement was 30,000. In addition, the imidization rate of the resin analyzed by ¹H-NMR was less than 5%.

### Synthesis of Polyimide Resin (A-5)

10.83 g (38.3 mmol) of 4,4-diamino-3,3-diethyl-5,5-dimethyldiphenylmethane, 25.77 g (41.7 mmol) of 4-[4-(1,3-dioxoisobenzofuran-5-ylcarbonyloxy)-2,3,5-trimethylphenyl]-2,3,6-trimethylphenyl 1,3-dioxoisobenzofuran-5-carboxylate, and 109.80 g of GBL were added to a suitably sized reaction container provided with a stirrer and cooling tube, and subjected to a polymerization reaction in a nitrogen atmosphere at 60 °C for 1.5 hours. Subsequently, the reaction liquid temperature was raised to 180 °C in an oil bath, a reaction was carried out for 3 hours, and then the result was cooled to room temperature to prepare a polyimide resin solution.

Subsequently, the reaction liquid was diluted with tetrahydrofuran to prepare a diluted solution and the diluted solution was then added dropwise to methanol to precipitate a white solid. The obtained white solid was recovered and vacuum dried at a temperature of 80 °C to obtain a polyimide resin (A-5) having an imide ring structure.

The weight-average molecular weight (Mw) of the resin (A-5) according to GPC measurement was 55,900. In addition, the imidization rate of the resin analyzed by ¹H-NMR was 95% or more.

### Synthesis of Silane Coupling Agent (C-1)

26.0 g (0.10 mol) of 3-trimethoxysilylpropylsuccinic anhydride and 494.0 g of gamma-butyrolactone were charged into a 1 L separable flask and stirred at room temperature for 1 hour. Next, 35.59 g (2.00 mol) of distilled water was slowly added dropwise while stirring. The result was stirred at room temperature for 16 hours and a 4.7% GBL solution of a silane coupling agent (C-1) was obtained.

### Synthesis of Adhesive Agent (E-1)

200.23 g (1.00 mol) of 4-hydroxybutyl acrylate glycidyl ether and 691 g of GBL were charged into a separable flask provided with a stirring device and stirred and dissolved at room temperature. Furthermore, 96.07 g (0.95 mol) of 3-mercapto-1,2,4-triazole was added thereto while stirring. Next, the solution was heated to 60 °C in an oil bath, further reacted at 60 °C for 6 hours, and a 30% GBL solution of an adhesive agent (E-1) was obtained.

### [Preparation of Photosensitive Resin Composition]

Each of the raw materials was blended according to Table 1 below and stirred at room temperature until the raw materials were completely dissolved. After stirring, the moisture content in the varnish was measured using a Karl Fischer moisture meter, water was added to reach the desired moisture content, and further stirring was performed at room temperature. Thereafter, the solution was filtered through a polypropylene filter having a pore size of 0.2 μm. In this manner, a varnish-like photosensitive resin composition was obtained.

In Table 1, the values for the blending composition of the adhesive agent (E-1) are the values for the mass of solid content excluding GBL.

In addition, the moisture content (% by mass) in the varnish is the value measured using a Karl Fischer moisture meter for the moisture content in the varnish, including all of the moisture added as a raw material during blending, the moisture included in the silane coupling agent (C-1), and the moisture mixed in during the preparation of the composition.

The details of the raw materials for each component in Table 1 below are as follows.

### <Resin (A)>

(A-1): Polyimide resin (A-1) having an imide ring structure synthesized as described above
(A-2): Polyimide resin (A-2) having an imide ring structure synthesized as described above
(A-3): Polyimide resin (A-3) having an imide ring structure synthesized as described above
(A-4): Polyimide precursor synthesized above <For Comparative Example>
(A-5): Polyimide resin (A-5) having an imide ring structure synthesized as described above

### <Photosensitizer (B)>

(B-1): Irugacure OXE01 (manufactured by BASF, oxime ester type photoradical generator)

### <Silane Coupling Agent (C)>

(C-1): 4.7% GBL solution of the silane coupling agent (C-1) synthesized as described above
(C-2): KBM-403E (manufactured by Shin-Etsu Chemical Co., Ltd., silane coupling agent having an epoxy group)

### <Polyfunctional (Meth)Acryl Compounds>

(D-1): NK Ester A-9550 (manufactured by Shin-Nakamura Chemical Co., Ltd., dipentaerythritol polyacrylate, a compound having 5 to 6 acryloyl groups in one molecule)
(D-2): Viscoat #230 (manufactured by Osaka Organic Chemical Industry Co., Ltd., a compound having 2 acryloyl groups in one molecule)

### <Adhesive Agent>

(E-1): 30% GBL solution of the adhesive agent (E-1) prepared by the synthesis described above

### <Epoxy Compounds>

(F-1): 4HBAGE (manufactured by Shinryo Corporation, 4-hydroxybutyl acrylate glycidyl ether)
(F-2): VG3101 L (manufactured by Printec Corporation, trifunctional epoxy compound)

### <Solvents>

(G-1): Ethyl lactate (EL)
(G-2): Gamma-butyrolactone (GBL)

TABLE 1

| | | | Example 1 | Example 2 | Example 3 | Example 4 | Example 5 | Example 6 | Example 7 |
|---|---|---|---|---|---|---|---|---|---|
| Blending | Resin | (A-1) | 100 | 100 | 100 | 100 | 100 | — | — |
| composition | | (A-2) | — | — | — | — | — | 100 | — |
| [parts by | | (A-3) | — | — | — | — | — | — | 100 |
| mass] | | (A-4) | — | — | — | — | — | — | — |
| | | (A-5) | — | — | — | — | — | — | — |
| | Photosensitizer | (B-1) | 10 | 10 | 10 | 10 | 10 | 10 | 10 |
| | Silane coupling | (C-1) | 1 | 1 | 1 | 1 | 1 | 1 | 1 |
| | agent | (C-2) | 5 | 5 | 5 | 5 | 5 | 5 | 5 |
| | Polyfunctional | (D-1) | 40 | 40 | 40 | 40 | 40 | 40 | 40 |
| | (meth)acrylate | (D-2) | 5 | 5 | 5 | 5 | 5 | 5 | 5 |
| | compound | | | | | | | | |
| | Adhesive | (E-1) | 4 | 4 | 4 | 4 | 4 | 4 | 4 |
| | Epoxy resin | (F-1) | 5 | 5 | 5 | 5 | 5 | 5 | — |
| | | (F-2) | 5 | 5 | 5 | 5 | 5 | 5 | — |
| | Organic solvent | (G-1) | 204 | 204 | 204 | 204 | 204 | 204 | — |
| | | (G-2) | 204 | 204 | 204 | 204 | 204 | 204 | 405 |
| | Moisture | | 4.5 | 0 | 1.1 | 14.4 | 25.5 | 6.3 | 6.1 |

| Moisture content in varnish | [% by | 1.5 | 0.30 | 0.60 | 3.0 | 5.0 | 1.5 | 1.5 |
|---|---|---|---|---|---|---|---|---|
| | mass] | | | | | | | |
| Moisture content relative to 100 | [parts | 5.0 | 1.0 | 2.0 | 10.0 | 16.7 | 5.0 | 5.2 |
| parts by mass of all solid components | by | | | | | | | |
| | mass] | | | | | | | |
| Varnish appearance | — | Excellent | Excellent | Excellent | Excellent | Excellent | Excellent | Excellent |
| 90° peel strength (copper adhesion) | [N/cm] | 2.0 | 1.5 | 1.7 | 1.9 | 2.0 | 2.2 | 1.9 |
| 90° peel strength fluctuation number | [%] | 20 | 34 | 24 | 11 | 15 | 14 | 21 |
| Patterning property | — | Excellent | Excellent | Excellent | Excellent | Excellent | Excellent | Excellent |
| Viscosity change rate at room | [%] | Excellent | Excellent | Excellent | Excellent | Excellent | Excellent | Excellent |
| temperature | | | | | | | | |
| Tg | [°C] | 270 | 260 | 260 | 260 | 270 | 260 | 265 |
| Elongation | [%] | 52 | 55 | 53 | 56 | 55 | 45 | 60 |

| | | | | | Comparative | Comparative | Comparative | Comparative |
|---|---|---|---|---|---|---|---|---|
| | | | Example 8 | Example 9 | example 1 | example 2 | example 3 | example 4 |
| Blending | Resin | (A-1) | 100 | — | — | 100 | 100 | — |
| composition | | (A-2) | — | — | — | — | — | — |
| [parts by | | (A-3) | — | — | — | — | — | — |
| mass] | | (A-4) | — | — | 100 | — | — | — |
| | | (A-5) | — | 100 | — | — | — | 100 |
| | Photosensitizer | (B-1) | 10 | 10 | 10 | 10 | 10 | 10 |
| | Silane coupling | (C-1) | 1 | 1 | 1 | 0.5 | 1 | 0.5 |
| | agent | (C-2) | 5 | 5 | 5 | 5 | 5 | 5 |
| | Polyfunctional | (D-1) | 40 | 40 | 40 | 40 | 40 | 40 |
| | (meth)acrylate | (D-2) | 5 | 5 | 5 | 5 | 5 | 5 |
| | compound | | | | | | | |
| | Adhesive | (E-1) | 4 | 4 | 4 | 4 | 4 | 4 |
| | Epoxy resin | (F-1) | 5 | 5 | 5 | 5 | 5 | 5 |
| | | (F-2) | 5 | 5 | 5 | 5 | 5 | 5 |
| | Organic solvent | (G-1) | 204 | — | 204 | 204 | 204 | — |
| | | (G-2) | 204 | 405 | 204 | 204 | 204 | 405 |
| | Moisture | | 56.5 | 16.2 | 25.5 | — | 59 | 0 |

| Moisture content in varnish | [% by | 9.1 | 3.0 | 5.0 | 0.20 | 11.0 | 0.20 |
|---|---|---|---|---|---|---|---|
| | mass] | | | | | | |
| Moisture content relative to 100 | [parts | 30.3 | 9.9 | 16.7 | 0.7 | 36.7 | 0.7 |
| parts by mass of all solid components | by | | | | | | |
| | mass] | | | | | | |
| Varnish appearance | — | Excellent | Excellent | Excellent | Excellent | Acceptable | Excellent |
| 90° peel strength (copper adhesion) | [N/cm] | 2.0 | 1.8 | 1.8 | 0.8 | — | 0.7 |
| 90° peel strength fluctuation number | [%] | 13 | 10 | 11 | 75 | — | 72 |
| Patterning property | — | Excellent | Excellent | Excellent | Excellent | — | Excellent |
| Viscosity change rate at room | [%] | Excellent | Excellent | Unacceptable | Excellent | — | Excellent |
| temperature | | | | | | | |
| Tg | [°C] | 270 | 260 | 260 | 260 | — | 260 |
| Elongation | [%] | 55 | 52 | 38 | 55 | — | 52 |

The obtained photosensitive resin composition was evaluated based on the items listed in Table 1.

In Table 1, “-” means that no evaluation was performed.

### <Moisture Content in Varnish>

The moisture content in the obtained photosensitive resin composition (varnish) was measured in accordance with the volumetric titration method specified in JIS K 0113:2005 using a Karl Fischer moisture meter “Model: CA-31” (product name, manufactured by Nitto Seiko Analytech Co., Ltd.) and a moisture vaporizer “Model: VA-230” (manufactured by Nitto Seiko Analytech Co., Ltd.) and using a Karl Fischer reagent “Aquamicron Water Standard Solution” (manufactured by Mitsubishi Chemical Corporation) as the titration reagent.

Specifically, the moisture content in the obtained photosensitive resin composition (varnish) was measured by the following method.

The mass (mg) of water generated from the photosensitive resin composition when heated to 170 °C was measured in accordance with the volumetric titration method specified in JIS K 0113:2005 under the condition of a nitrogen gas flow rate of 250 mL/min using a Karl Fischer moisture meter and a moisture vaporizer and using a Karl Fischer reagent as the titration reagent. Next, the water content ratio when the total amount of the photosensitive resin composition (varnish) was 100% by mass was determined and set as the moisture content (% by mass).

### <Varnish Appearance Measurement>

The obtained photosensitive resin composition was left to stand at 23 °C for 24 hours and the appearance was observed. Normal compositions without turbidity or precipitation were rated as “excellent”, compositions in which turbidity was generated were rated as “acceptable”, and compositions in which precipitation was generated were rated as “unacceptable”.

### <Adhesion: 90° Peel Strength>

### (Creation of Evaluation Substrate for 90° Peel Strength)

The obtained photosensitive resin composition was coated by spin coating on a 12-inch silicon wafer having a 3000 Å plated copper layer on the surface such that the film thickness after drying was 10 μm, and then heated at 120 °C for 3 minutes to obtain a photosensitive resin film.

The obtained photosensitive resin film was exposed to light at 300 mJ/cm² through a photomask using an i-line stepper such that a range 6.5 mm wide and 50 mm long was exposed to light. Thereafter, the light-exposed resin film was developed together with the silicon wafer using a spray developer with cyclopentanone and propylene glycol monomethyl ether acetate, further air-dried using a spin dryer, and then dried on a hot plate at 120 °C for 2 minutes. Thereafter, the result was heat-treated in a nitrogen atmosphere at 200 °C for 90 minutes to obtain a cured film.

Subsequently, the silicon wafer was cut such that the obtained cured film, which was 6.5 mm in width and 50 mm in length, remained and the end (5 mm) of the cured film was immersed in a 2% aqueous hydrofluoric acid solution at 23 °C for 6 hours and then washed with water and dried to obtain an evaluation substrate for 90° peel strength with the film at the end peeled off.

### (90° Peel Strength)

The substrate obtained according to the above (Creation of evaluation substrate for 90° peel strength) was set in a 90° peel strength measuring device (manufactured by Shimadzu Corporation, AUTOGRAPH AG-Xplus), 1 cm thereof was peeled off under the condition of a peel speed of 20 mm/min, and the maximum value of the peel strength at this time was evaluated.

10 samples were evaluated, the average value of the peel strength of the 10 samples was calculated as the peel strength, and the measurement variation in the 10 samples calculated from the following formula was evaluated as the fluctuation number.

Fluctuation number[%]=(maximum value−minimum value)/average value×100

The unit of the 90° peel strength is N/cm. A higher 90° peel strength is more preferable in terms of reliability.

### <Patterning Evaluation>

The obtained photosensitive resin composition was spin-coated onto a 12-inch silicon wafer having a 3000 Å plated copper layer on the surface such that the film thickness after drying was 5 μm, and dried on a hot plate at 120 °C for 3 minutes to obtain a photosensitive resin film. Through a mask (Test Chart No. 1: in which retained patterns and cut-out patterns having widths of 0.5 to 50 μm were drawn) manufactured by Toppan Printing Co., Ltd., this photosensitive resin film was irradiated with i-line light using an i-line stepper (manufactured by Canon, FPA-5500iX) while changing the light exposure dose.

The light-exposed film was developed using cyclopentanone at 2500 rpm for 30 seconds using a spray developer, then using propylene glycol monomethyl ether acetate at 2500 rpm for 10 seconds, further air-dried using a spin dryer at 2500 rpm for 10 seconds, and then dried on a hot plate at 120 °C for 2 minutes. Thereafter, the film was heat-treated at 200 °C for 90 minutes in a nitrogen atmosphere to obtain a patterned resin film.

The obtained patterns were observed and rated as “excellent” (very good) when via holes less than 5 μm (were opened, “good” (good) when via holes of 5 μm (or more and 10 μm (or less were opened, and “unacceptable” (poor) when via holes of 10 μm (or more were opened.

### <Room Temperature Viscosity Change Rate>

The viscosity of the photosensitive resin composition immediately after blending was measured using an E-type viscometer (TVE-25 L). The viscosity at this time was set as A. Thereafter, the varnish of the photosensitive resin composition used to measure the viscosity A was stored at 23 °C for 7 days and the viscosity was measured again. The viscosity at this time was set as B.

The “viscosity change rate” was calculated based on the following formula using the values of viscosity A and viscosity B. A viscosity change rate of ±3% or less was rated as “excellent” (very good), a rate of more than ±3% and 8% or less was rated as “good” (good), and a rate of more than ±8% was rated as “unacceptable” (poor). A lower viscosity change rate is better for obtaining a stable film thickness.

Viscosity change rate[%]={(viscosity A−viscosity B)/viscosity A}×100

### <Heat Resistance: Evaluation of Glass Transition Temperature (Tg)>

### (Creation of Test Pieces for Measuring Glass Transition Temperature (Tg))

The obtained photosensitive resin composition was spin-coated onto an 8-inch silicon wafer such that the film thickness after drying was 10 μm, and then heated at 120 °C for 3 minutes to obtain a photosensitive resin film.

The obtained photosensitive resin film was exposed to light at 300 mJ/cm² with a high-pressure mercury lamp. Thereafter, the light-exposed resin film was immersed in cyclopentanone together with the silicon wafer for 30 seconds. Furthermore, a heat-treatment was carried out at 200 °C for 90 minutes in a nitrogen atmosphere. As a result, a cured product of the photosensitive resin composition was obtained.

The obtained cured product was cut together with the silicon wafer to a width of 5 mm using a dicing saw and then peeled off from the substrate by immersion in a 2% by mass aqueous hydrofluoric acid solution. The peeled film was dried at 60 °C for 10 hours to obtain a test piece (30 mm×5 mm×10 μm thick).

### (Measurement of Glass Transition Temperature (Tg))

The obtained test piece was heated to 300 °C at a heating rate of 10 °C/min using a thermomechanical analyzer (manufactured by Seiko Instruments Inc., TMA/SS6000) and the thermal expansion coefficient of the obtained test piece was measured.

Next, based on the obtained measurement results, the glass transition temperature (Tg) of the cured product was calculated from the inflection point of the thermal expansion coefficient. The unit of Tg is °C.

### <Measurement of Tensile Elongation>

### (Creation of Test Pieces for Measuring Tensile Elongation)

The photosensitive resin compositions of each Example and Comparative Example were spin-coated onto a 12-inch silicon wafer such that the film thickness after drying was 10 μm, and then heated at 120 °C for 3 minutes to obtain a photosensitive resin film. The obtained coating film was exposed to light at 300 mJ/cm² through a photomask using an i-line stepper such that a range 5 mm wide and 50 mm long was exposed to light. Thereafter, the light-exposed resin film was then developed with cyclopentanone and propylene glycol monomethyl ether acetate together with the silicon wafer using a spray developer, further air-dried using a spin dryer, and then dried on a hot plate at 140 °C for 2 minutes. Thereafter, a heat-treatment was carried out at 200 °C for 120 minutes in a nitrogen atmosphere to obtain a resin film.

The obtained resin film was peeled off from the substrate by immersion in a 2% by mass aqueous solution of hydrofluoric acid, washed with water, and then dried at 60 °C for 10 hours to obtain a test piece for measurement (50 mm×5 mm×10 μm thick).

### (Measurement of Tensile Elongation)

A tensile test was carried out on the test piece for measurement obtained in the above (Creation of test pieces for measuring tensile elongation) using a tensile tester (manufactured by Orientec Co., Ltd., Tensilon RTC-1210A) in a 23 °C atmosphere using a method in accordance with JIS K 7161, and the tensile elongation of the test piece was measured. The extension speed in the tensile test was 5 mm/min. The unit of tensile elongation is %.

In the results, the photosensitive resin compositions of Examples 1 to 6 exhibited excellent storage stability due to having a smaller room temperature viscosity change rate than Comparative Example 1 and a better varnish appearance than Comparative Example 3, and also exhibited excellent copper adhesion stability due to having a smaller 90° peel strength fluctuation number than Comparative Example 2.

In addition, in the results, the photosensitive resin compositions of Examples 7 to 9 exhibited excellent storage stability due to having a smaller room temperature viscosity change rate than Comparative Example 1 and a better varnish appearance than Comparative Example 3, and also exhibited excellent copper adhesion stability due to having a smaller 90° peel strength fluctuation number than Comparative Examples 2 and 4.

This application claims priority based on Japanese Patent Application No. 2022-142797 filed on Sep. 8, 2022, the entire disclosure of which is incorporated herein by reference.

### REFERENCE SIGNS LIST

1 Electronic device
1A Electronic device
1B Electronic device
2 Through electrode substrate
3 Semiconductor package
5 Photosensitive resin varnish
21 Insulating layer
23 Semiconductor chip
24 Lower wiring layer
24A Lower wiring layer
24B Lower wiring layer
25 Upper wiring layer
26 Solder bump
27 Chip-embedded structure
31 Package substrate
32 Semiconductor chip
33 Bonding wire
34 Sealing layer
35 Solder bump
202 Substrate
221 Through wire
222 Through wire
231 Land
240 Organic insulating layer
241 Organic insulating layer
242 Organic insulating layer
243 Wiring layer
245 Bump adhesion layer
251 Organic insulating layer
252 Organic insulating layer
253 Wiring layer
254 Through wire
412 Mask
423 Opening
424 Opening
2510 Photosensitive resin layer
2520 Photosensitive resin layer
S1 Chip arranging step
S2 Upper wiring layer forming step
S20 First resin film arranging step
S21 First light exposure step
S22 First development step
S23 First curing step
S24 Wiring layer forming step
S25 Second resin film arranging step
S26 Second light exposure step
S27 Second development step
S28 Second curing step
S29 Through wire forming step
S3 Substrate peeling step
S4 Lower wiring layer forming step
S5 Solder bump forming step
S6 Laminating step
W Diameter

1. A photosensitive resin composition comprising:
a polyimide (A) having an imide ring structure in a molecule; and
a photosensitizer (B),
wherein a moisture content measured by a Karl Fischer method is 0.30% by mass or more and 10% by mass or less.

2. The photosensitive resin composition according to claim 1,
wherein the moisture content is 0.5% by mass or more and 6% by mass or less.

3. The photosensitive resin composition according to claim 1,
wherein, when a number of moles of imide ring groups included in the polyimide (A) is defined as IM,
a number of moles of amide groups included in the polyimide (A) is defined as AM, and
an imide cyclization rate expressed as {IM/(IM+AM)}×100(%) is 90% or more.

4. The photosensitive resin composition according to claim 1,
wherein a weight-average molecular weight of the polyimide (A) is 27,000 or more.

5. The photosensitive resin composition according to claim 1, further comprising:
a silane coupling agent (C).

6. The photosensitive resin composition according to claim 5,
wherein the silane coupling agent (C) includes a silane coupling agent including an acid anhydride group, and/or a silane coupling agent having a structure in which a part of a structure derived from an acid anhydride group is ring-opened.

7. The photosensitive resin composition according to claim 1, further comprising:
an epoxy compound.

8. The photosensitive resin composition according to claim 7,
wherein the epoxy compound includes a compound having one or more epoxy-containing groups and one or more (meth)acryloyl groups in one molecule.

9. The photosensitive resin composition according to claim 1, further comprising:
an organic solvent,
wherein the photosensitive resin composition is varnish-like.

10. The photosensitive resin composition according to claim 1,
wherein a total solid content concentration in the photosensitive resin composition is 10% to 50% by mass.

11. The photosensitive resin composition according to claim 1,
wherein a glass transition temperature of a cured film of the photosensitive resin composition is 200 °C or higher.

12. The photosensitive resin composition according to claim 1,
wherein a 90° peel strength fluctuation number according to a method below is 70% or less,
(Method)
the photosensitive resin composition is coated by spin coating onto a 12-inch silicon wafer having a 3000 Å plated copper layer over a surface such that a film thickness after drying is 10 μm, and then heated at 120 °C for 3 minutes to obtain a photosensitive resin film, next, the photosensitive resin film is exposed to light at 300 mJ/cm² through a photomask using an i-line stepper such that a range 6.5 mm wide and 50 mm long is exposed to light, next, the photosensitive resin film is developed with cyclopentanone and propylene glycol monomethyl ether acetate together with the silicon wafer using a spray developer, further air-dried using a spin dryer, then dried over a hot plate at 120 °C for 2 minutes, and then heat-treated in a nitrogen atmosphere at 200 °C for 90 minutes to obtain a cured film, next, the silicon wafer is cut such that the cured film 6.5 mm wide and 50 mm long remains, and a longitudinal direction end (5 mm) of the cured film is immersed in a 2% aqueous hydrofluoric acid solution at 23 °C for 6 hours, and then washed with water and dried to obtain an evaluation substrate with an end of the film peeled off, next, 1 cm of the evaluation substrate is peeled off using a 90° peel strength measuring device under a condition of a peel speed of 20 mm/min, and a maximum value of the peel strength at this time is measured as a peel strength, and then, ten samples are measured, an average value of the peel strengths of the ten samples is calculated as the peel strength, and a measurement variation in the ten samples calculated from a formula below is set as the 90° peel strength fluctuation number,
fluctuation number[%]=(maximum value−minimum value)/average value×100.

13. The photosensitive resin composition according to claim 1,
wherein, when a viscosity of the photosensitive resin composition is defined as η₀,
a viscosity of the photosensitive resin composition after leaving the photosensitive resin composition to stand for 7 days at 23 °C is defined as η₁, and
a value of η₁/η₀ is 1.5 or less.

14. The photosensitive resin composition according to claim 1,
wherein the photosensitizer (B) includes a photoradical generator.

15. The photosensitive resin composition according to claim 1,
wherein the photosensitive resin composition is a negative-type photosensitive resin composition.

16. A resin film formed of a cured product of the photosensitive resin composition according to claim 1.

17. An electronic device comprising:
the resin film according to claim 16.

18. A method for producing a photosensitive resin composition, the method comprising:
a step of obtaining a photosensitive resin composition by dissolving a polyimide (A) having an imide ring structure in a molecule and a photosensitizer (B) in a solvent,
wherein the step of obtaining the photosensitive resin composition has a step of adjusting a moisture content in the photosensitive resin composition measured by a Karl Fischer method to be 0.30% by mass or more and 10% by mass or less.

19. The method for producing a photosensitive resin composition according to claim 18, the method further comprising:
a step of preparing an aqueous solution including a silane coupling agent (C) and water, and adding the aqueous solution to the photosensitive resin composition.
